(19) United States
(12) Patent Application Publication
(10) Pub. No.: US 2016/0315096 A1
(43) Pub. Date: Oct. 27, 2016

(54) SEMICONDUCTOR MEMORY DEVICE AND SEMICONDUCTOR WAFER

(71) Applicant: KABUSHIKI KAISHA TOSHIBA, Minato-ku (JP)

(72) Inventor: Takeshi IMAMURA, Yokkaichi (JP)

(73) Assignee: KABUSHIKI KAISHA TOSHIBA, Minato-ku (JP)

(21) Appl. No.: 15/000,287

(22) Filed: Jan. 19, 2016

Related U.S. Application Data
(60) Provisional application No. 62/152,426, filed on Apr. 24, 2015.

(51) Int. Cl. H01L 27/115; H01L 23/528

(52) U.S. Cl. CPC H01L 27/11582; H01L 27/11521; H01L 27/11526; H01L 27/11556; H01L 27/11568; H01L 27/11573; H01L 23/528

(57) ABSTRACT

According to one embodiment, the embodiment includes memory cells, a memory cell array, a first stepped portion, and a second stepped portion. The memory cell array includes memory cells and a plurality of conducting layers. n. The plurality of conducting layers are coupled to the memory cells. The first stepped portion includes the plurality of conducting layers. Height of the first stepped portion decrements with separation from the memory cell array. The second stepped portion has a structure in which a plurality of first layers and second layers are laminated in alternation on the semiconductor substrate. The second stepped portion is disposed opposing the first stepped portion. Height of the second stepped portion increments with separation from the memory cell array. A lowest surface of the second stepped portion is formed at a position higher than the conducting layer at a lowest layer of the first stepped portion.

### CROSS REFERENCE TO RELATED APPLICATION

This application is based upon and claims the benefit of priority from U.S. Provisional Patent Application No. 62/152,426, filed on Apr. 24, 2015, the entire contents of which are incorporated herein by reference.

### FIELD

Embodiments described herein relate generally to a semiconductor memory device and a semiconductor wafer.

### BACKGROUND

### Description of the Related Art

There has been known a flash memory that accumulates electric charges on an electric charge accumulating layer to store data. Such flash memory is coupled by various methods such as a NAND type and a NOR type, thus constituting a semiconductor memory device. Recently, such semiconductor memory devices have been large capacity and highly integrated. To enhance a degree of integration of the memory, a semiconductor memory device whose memory cells are three-dimensionally disposed (three-dimensional semiconductor memory device) has been proposed.

### BRIEF DESCRIPTION OF THE DRAWINGS

FIG. 1 is a plan view illustrating a schematic constitution of a semiconductor memory device according to a first embodiment;

FIG. 2 is a schematic plan view illustrating a state of a wafer 101A according to the embodiment;

FIG. 3 is a schematic plan view of the wafer 101A;

FIG. 4 is a schematic plan view of the wafer 101A;

FIG. 5 is a schematic cross-sectional view of the wafer 101A;

FIG. 6 is a schematic plan view of a wafer according to another exemplary configuration;

FIG. 7 is a schematic plan view of a wafer according to another exemplary configuration;

FIG. 8 is a perspective view illustrating a constitution of a memory cell array 1 of the semiconductor memory device;

FIGS. 9A and B are schematic cross-sectional views illustrating the constitution of the semiconductor memory device,

FIG. 10 is a schematic cross-sectional view illustrating the constitution of the semiconductor memory device;

FIG. 11 to FIG. 22 are schematic cross-sectional views illustrating a method for manufacturing the semiconductor memory device;

FIGS. 23A and B are schematic cross-sectional views illustrating the constitution of the semiconductor memory device according to a second embodiment;

FIG. 24 to FIG. 28 are schematic cross-sectional views illustrating a method for manufacturing the semiconductor memory device;

FIG. 29 to FIG. 31 are schematic cross-sectional views illustrating a method for manufacturing the semiconductor memory device according to a modification;

FIG. 32 to FIG. 34 are schematic cross-sectional views illustrating a method for manufacturing the semiconductor memory device according to another modification;

and

FIG. 35 to FIG. 37 are schematic cross-sectional views illustrating a method for manufacturing the semiconductor memory device according to yet another modification.

FIG. 38 is a schematic cross-sectional view illustrating a the constitution of the semiconductor memory device according to yet another modification,

FIG. 39 is a perspective view illustrating a constitution of a memory cell array 1 of the semiconductor memory device according to yet another modification,

FIG. 40 is a schematic cross-sectional view illustrating a the constitution of the semiconductor memory device according to yet another modification,

FIG. 41 is a perspective view illustrating a constitution of a memory cell according to the embodiments,

### DETAILED DESCRIPTION

According to one embodiment, a semiconductor memory device includes a memory cell array, a first stepped portion, and a second stepped portion. The memory cell array includes memory cells arranged on a semiconductor substrate in a laminating direction and a plurality of conducting layers. The plurality of conducting layers are arranged on the semiconductor substrate in the laminating direction. The plurality of conducting layers are coupled to the memory cells. The first stepped portion includes the plurality of conducting layers. Height of the first stepped portion decrements with separation from the memory cell array. The second stepped portion has a structure in which a plurality of first layers and second layers are laminated in alternation on the semiconductor substrate in the laminating direction. The second stepped portion is disposed opposing the first stepped portion, and height of the second stepped portion increments with separation from the memory cell array. A second layer at a lowest layer of the second stepped portion is formed at a position higher than the conducting layer at a lowest layer of the first stepped portion.

The following describes semiconductor memory devices according to embodiments in detail with reference to the accompanying drawings. Here, these embodiments are only examples. For example, the semiconductor memory device described below has a structure where a memory string extends in a straight line in the vertical direction with respect to a substrate. The similar structure is also applicable to the structure having a U shape where a memory string is folded to the opposite side in the middle. The respective drawings of the semiconductor memory devices used in the following embodiments are schematically illustrated. The thickness, the width, the ratio, and a similar parameter of the layer are not necessarily identical to actual parameters.

The following embodiment relates to a semiconductor memory device in a structure where a plurality of metal-oxide-nitride-oxide-semiconductor (MONOS) type memory cells (transistors) is disposed in a height direction. The MONOS type memory cell includes: a semiconductor film disposed in a columnar shape vertical to the substrate as a channel, and a gate electrode film disposed on the side surface of the semiconductor film via an electric charge accumulating layer. However, a similar structure is applicable to another type, for example, a semiconductor-oxide-nitride-oxide-semiconductor type (SONOS) memory cell, a metal-aluminum oxide-nitride-oxide-semiconductor type (MANOS) memory cell, a memory cell that uses hafnium oxide (HfOₓ) or tantalum oxide (TaOₓ) as an insulating layer, or a floating-gate type memory cell.

### First Embodiment

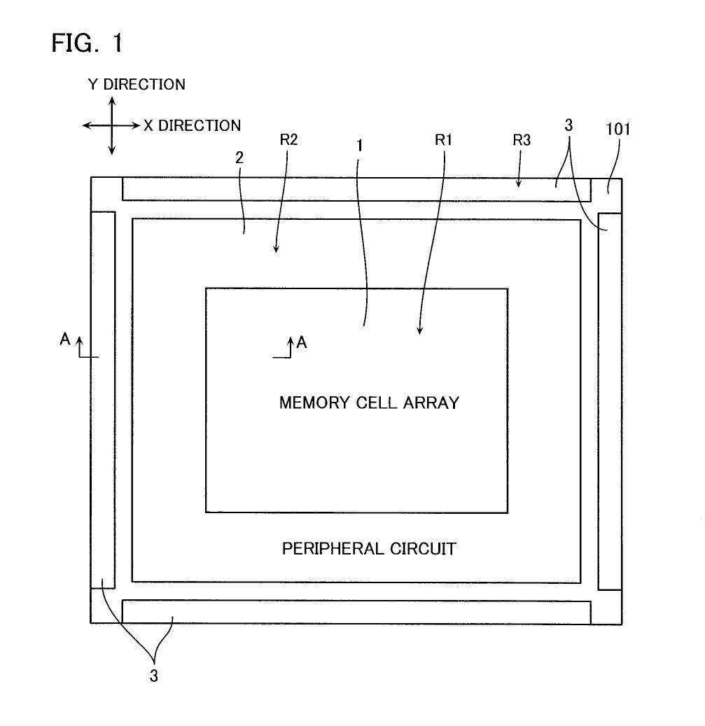

FIG. 1 is a plan view illustrating a schematic constitution of a semiconductor memory device according to a first embodiment. The semiconductor memory device according to the first embodiment includes a memory cell array 1, a peripheral circuit 2, and dummy stepped portions 3, which are disposed on a substrate 101 used as a memory chip.

The memory cell array 1 includes a plurality of memory cells and a stepped portion. The memory cells are three-dimensionally arranged. The stepped portion is formed by wirings extracted from the memory cells in a stepped pattern.

The peripheral circuit 2 is coupled to the memory cell array 1 via a plurality of bit lines and a plurality of word lines. The peripheral circuit 2 is constituted of a CMOS circuit disposed on the substrate 101. The peripheral circuit 2 functions as a decoder, a sense amplifier, a state machine, a voltage generating circuit, or a similar circuit.

The dummy stepped portions 3 are disposed along edge portions of the substrate 101 in an X direction and a Y direction so as to surround the memory cell array 1 and the peripheral circuit 2. The dummy stepped portion 3 is, as described later, formed into the stepped pattern of which height increments with separation from the memory cell array 1. In the example illustrated in FIG. 1, the dummy stepped portions 3 are each disposed at the all four sides of the substrate 101. However, the dummy stepped portion 3 may be disposed only at one side of the substrate 101. Alternatively, the dummy stepped portions 3 may be disposed at two sides or three sides of the substrate 101. In FIG. 1, the edge portions of the dummy stepped portions 3 positioned at adjacent two sides of the substrate 101 are disposed separately from one another. However, the dummy stepped portions 3 may be coupled to one another.

In the following description, a region on the substrate 101 where the memory cell array 1 is disposed is referred to as a memory cell array region R1. A region on the substrate 101 where the peripheral circuit 2 is disposed is referred to as a peripheral circuit region R2 (transistor region). Additionally, a region on the substrate 101 where the dummy stepped portion 3 is disposed is referred to as a dummy stepped region R3. The peripheral circuit region R2 is formed at a region sandwiched between the memory cell array region R1 and the dummy stepped region R3.

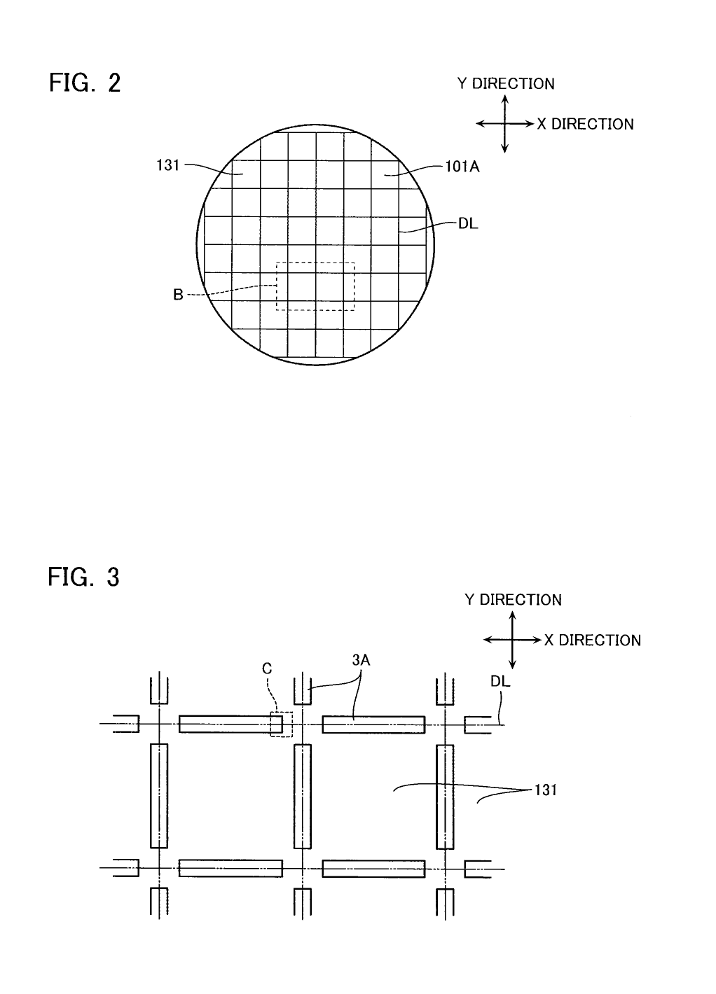

With reference to FIG. 2 to FIG. 7, the following describes a wafer 101A from which the semiconductor memory device is fabricated. FIG. 2 is a schematic plan view illustrating a state of the wafer 101A. The wafer 101A is divided into a plurality of chip regions 131 at a plurality of dicing lines DL disposed along the X direction and the Y direction. The wafer 101A is separated along the dicing lines DL to form these plurality of respective chip regions 131. Thus, each chip region 131 becomes the semiconductor memory device as illustrated in FIG. 1.

FIG. 3 is a schematic plan view of the wafer 101A. FIG. 3 illustrates the enlarged part shown by reference numeral B in FIG. 2. As illustrated in FIG. 3, kerf portions 3A are disposed at boundary parts of the plurality of chip regions 131 along the dicing lines DL. As illustrated in an enlarged plan view and a cross-sectional view, which will be described later, the kerf portion 3A has a structure in the stepped pattern. In the stepped pattern, the height of the kerf portion 3A increments with separation from the chip region 131 in the short direction of the kerf portion 3A. By separating the wafer 101A along the dicing lines DL, the stepped structure at the dicing line DL part becomes the dummy stepped portion 3. That is, the kerf portion 3A has the dummy stepped portions 3 on both short sides.

The kerf portions 3A are disconnected at the part of intersecting the dicing lines DL. That is, at the portion where the dicing lines DL intersect, the kerf portion 3A is not formed, being discontinuous.

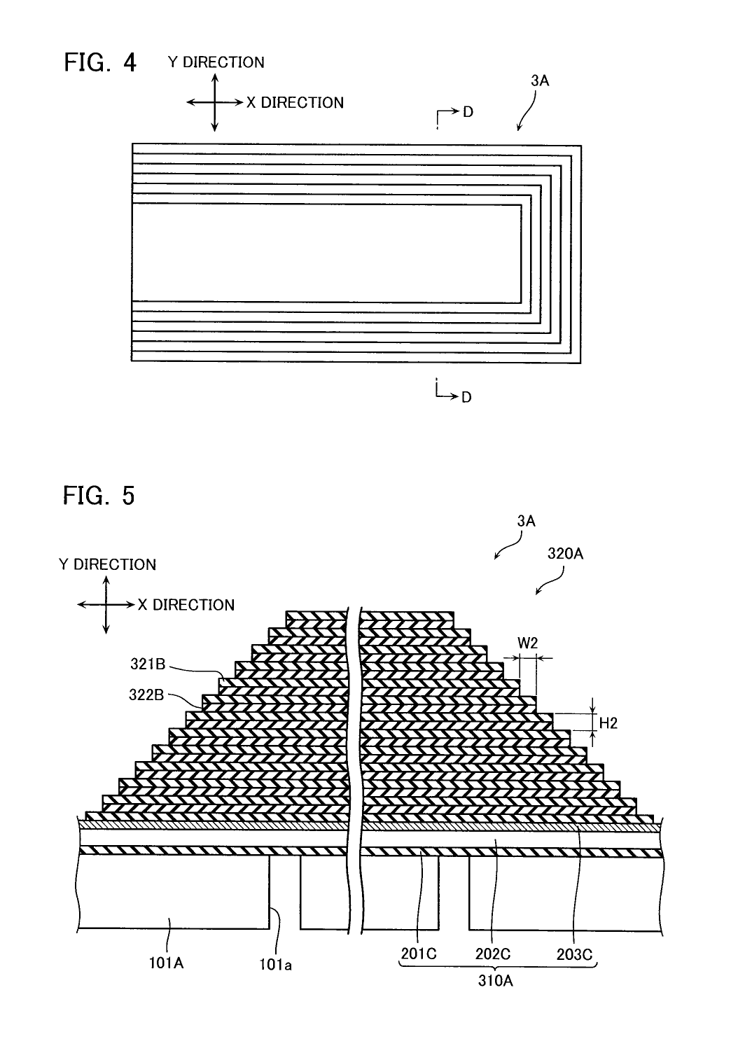

FIG. 4 is a schematic plan view of a part of the wafer 101A enlarged at the part shown by reference numeral C in FIG. 3. FIG. 5 is a schematic cross-sectional view of the kerf portion 3A corresponding to the part shown by reference numeral D in FIG. 4. For ease of understanding, FIG. 4 and FIG. 5 illustrate the schematic constitutions; therefore, a count of layers, width, and a similar specification for both do not match.

As illustrated in FIG. 5, slits 101a are disposed at the wafer 101A along the dicing lines DL. As illustrated in FIG. 5, the kerf portion 3A includes an interposing portion 310A and a stepped portion 320A.

As illustrated in FIG. 5, the interposing portion 310A includes an insulating layer 201C, a polysilicon layer 202C, and a metal layer 203C, which are laminated on the wafer 101A. These insulating layer 201C, polysilicon layer 202C, and metal layer 203C are each made of materials identical to a gate insulating layer 201, a gate polysilicon layer 202, and a gate metal layer 203, which will be described later, and have a film thickness equivalent to these layers.

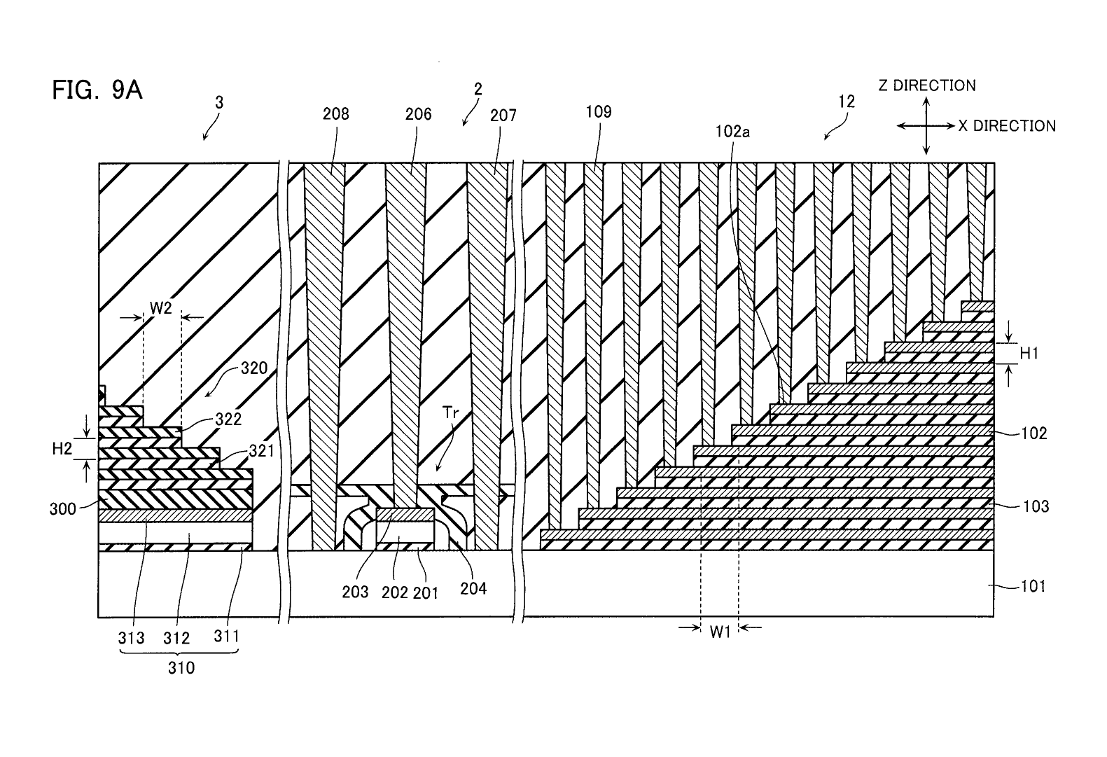

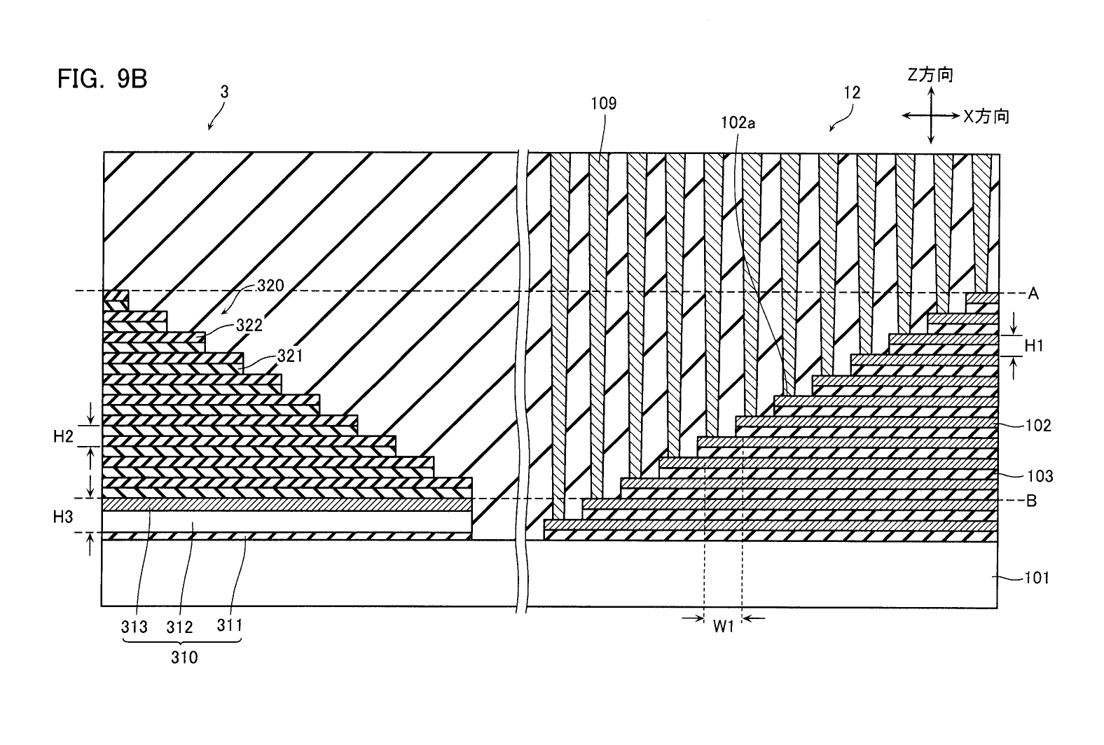

As illustrated in FIG. 5, the stepped portion 320A includes a plurality of insulating layers 321B and insulating layers 322B. The insulating layers 321B and the insulating layers 322B are laminated in alternation on the top surface of the metal layer 203C. These plurality of insulating layers 321B and insulating layers 322B are formed into the stepped pattern. A width W2 of one step of these steps in the X direction is equivalent to a width W1. The width W1 is a width of a contact portion 102a, which will be described later, in the X direction. Similarly, a width H2 of one step of these steps in a Z direction is equivalent to an interval H1. The interval H1 is an interval of a conducting layer 102 in the Z direction (see FIGS. 9A and 9B). The insulating layer 321B is, for example, made of oxide silicon (SiO₂). The insulating layer 322B is, for example, made of silicon nitride (SiN). A step count of these steps matches a step count of a stepped portion 12 of a memory cell block MB.

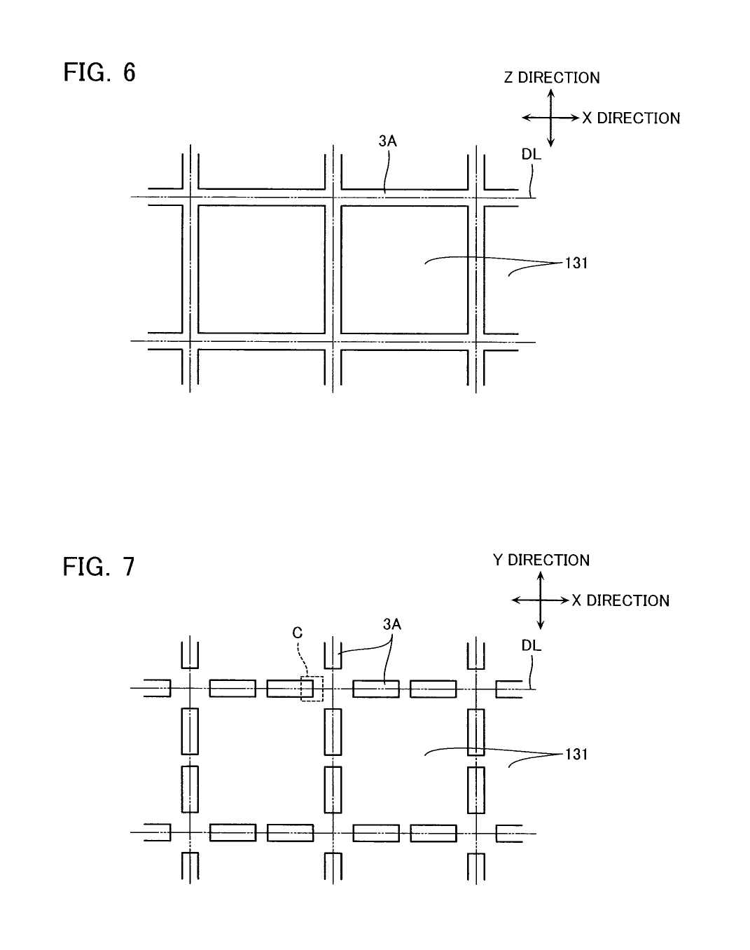

In the example illustrated in FIG. 3, the kerf portions 3A are disconnected at part of intersecting the dicing lines DL. Accordingly, the kerf portion 3A is not formed at the part of intersecting the dicing lines DL. That is, between the adjacent chip regions 131, the kerf portions 3A are discontinuous. However, for example, as illustrated in FIG. 6, the kerf portion 3A may be disposed also at the part of intersecting the dicing lines DL such that the kerf portion 3A is continuous at the part between the adjacent chip regions 131.

In this case, since the kerf portion 3A has the dummy stepped portions 3 on the short sides as described above, the dummy stepped portions 3 are also continuous at the part between the adjacent chip regions 131.

In the example illustrated in FIG. 6, the kerf portions 3A are integrally formed at the part of the intersection point of the dicing lines DL. However, as illustrated in FIG. 7, the disconnected part may be disposed at the part of the intersection point of the dicing lines DL. That is, the kerf portion 3A may also be discontinuous at the portion other than the portion of intersecting the dicing lines DL. In this case, since the kerf portion 3A has the dummy stepped portions 3 on the short sides as described above, the dummy stepped portions 3 are also discontinuous at the portion other than the portion of intersecting the dicing lines DL.

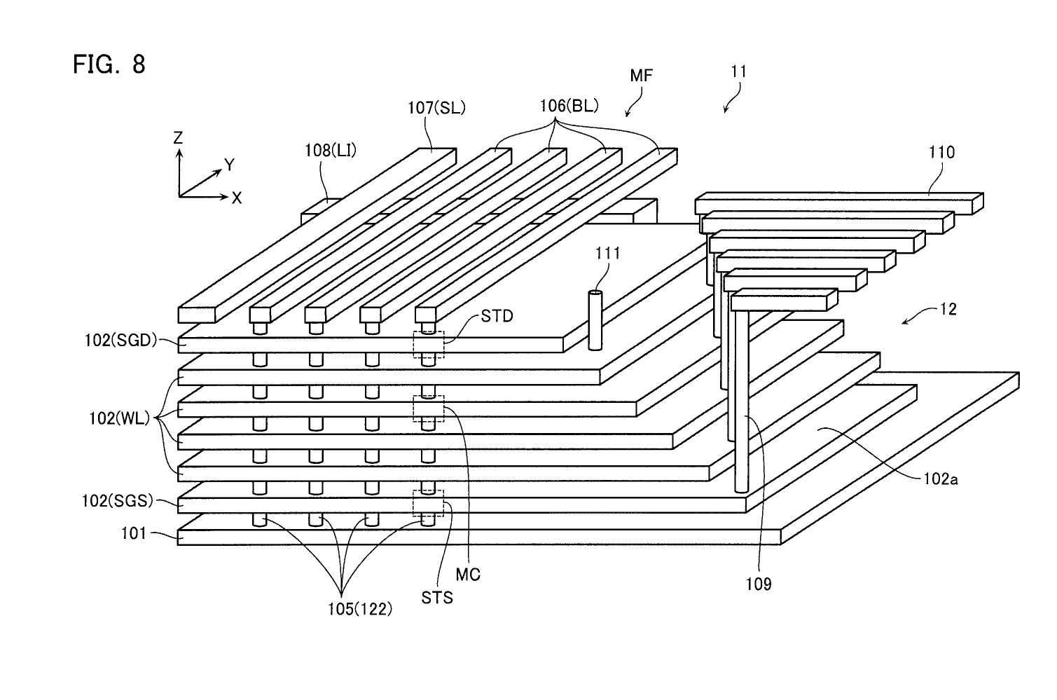

Next, with reference to FIG. 8, the following describes a schematic constitution of the memory cell array 1 according to the embodiment. FIG. 8 is a schematic, perspective view illustrating a constitution of a part of a memory finger MF (memory cell group). FIG. 8 omits a part of the constitution.

As illustrated in FIG. 8, the memory finger MF according to the embodiment includes the substrate 101 and the plurality of conducting layers 102. The conducting layers 102 are laminated on the substrate 101 in the Z direction. The memory finger MF has a plurality of memory shafts 105 extending in the Z direction. As illustrated in FIG. 8, the intersection portions of the conducting layers 102 and the memory shafts 105 function as a source-side selection gate transistor STS, a memory cell MC, or a drain-side selection gate transistor STD. The conducting layer 102 is a conducting layer made of, for example, tungsten (W) or polysilicon. The conducting layer 102 functions as a word line WL, a source-side selection gate line SGS, and a drain-side selection gate line SGD.

As illustrated in FIG. 8, the plurality of conducting layers 102 are formed into the stepped pattern at the edge portion in the X direction. This constitutes the stepped portion 12, which is described with reference to FIG. 1.

As illustrated in FIG. 8, the memory finger MF includes a conducting layer 108. The conducting layer 108 opposes the side surfaces of the plurality of conducting layers 102 in the Y direction and extends in the X direction. The lower surface of the conducting layer 108 is in contact with the substrate 101. The conducting layer 108 is a conducting layer made of, for example, tungsten (W). The conducting layer 108 functions as a source contact L1.

As illustrated in FIG. 8, conducting layers 106 and a conducting layer 107 are disposed over the memory finger MF. The conducting layers 106 function as a bit line BL while the conducting layer 107 functions as a source line SL.

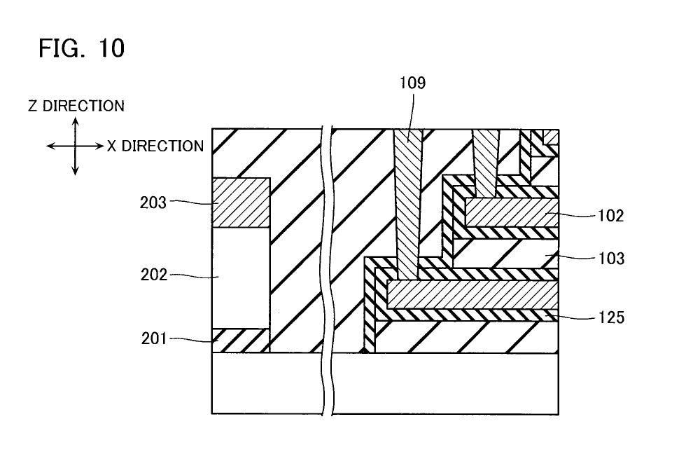

Next, with reference to FIG. 9A, FIG. 9B and FIG. 10, the following describes the constitution of the semiconductor memory device according to the first embodiment in further details. FIG. 9A and FIG. 9B are a schematic cross-sectional view illustrating the constitution of the semiconductor memory device according to the embodiment. FIG. 9 illustrates a cross section cut along the line AA in FIG. 1. FIG. 10 is a schematic cross-sectional view illustrating the constitution of the semiconductor memory device according to the embodiment. FIG. 10 illustrates enlarging a part of FIG. 9. FIG. 9 omits a part of the constitution. The constitution illustrated in FIG. 9 is merely an example. The detailed constitution or a similar constitution can be changed as necessary.

FIG. 9A illustrates the constitution of a part of the above-described stepped portion 12, peripheral circuit 2, and dummy stepped portion 3 of the memory cell array 1.

As illustrated in FIG. 9A, in the stepped portion 12, the plurality of conducting layers 102 are laminated via insulating layers 103 made of, for example, oxide silicon.

As illustrated in FIG. 10, the plurality of conducting layers 102 are covered with block insulating layers 125 formed of insulating layers made of, for example, oxide silicon (SiO₂). The block insulating layer 125, which covers the conducting layer 102, plays a role of a stopper film to form a via contact wiring 109.

As illustrated in FIG. 9A, in the stepped portion 12, the plurality of conducting layers 102 are formed into the stepped pattern. To the contact portion 102a of each conducting layer 102, the via contact wiring 109 is coupled.

As illustrated in FIG. 9A, the peripheral circuit 2 is constituted of the CMOS circuit including a plurality of transistors Tr. The transistor Tr has the gate insulating layer 201, the gate polysilicon layer 202, and the gate metal layer 203, which are laminated on the substrate 101. The transistor Tr includes a barrier layer 204. The barrier layer 204 covers the side surfaces and the top surface of these layers. A source contact via wiring 207 and a drain contact via wiring 208 are each coupled to a surface of the substrate 101. The substrate 101 functions as the source and the drain of the transistor Tr. Further, to the gate metal layer 203, a gate contact via wiring 206 is coupled. As described above, the gate insulating layer 201, the gate polysilicon layer 202, and the gate metal layer 203 are made of the materials identical to the insulating layer 201C, the polysilicon layer 202C, and the metal layer 203C and have the film thickness equivalent to these layers.

The gate insulating layer 201 is, for example, made of oxide silicon (SiO₂). The gate polysilicon layer 202 is, for example, made of polysilicon. The gate metal layer 203 is, for example, made of metal such as tungsten (W). The barrier layer 204 and the barrier layer 205 are, for example, constituted of the insulating layer made of, for example, silicon nitride (SiN).

As illustrated in FIG. 9A, the dummy stepped portion 3 includes an interposing portion 310 and a stepped portion 320. The interposing portion 310 is disposed on the substrate 101. The stepped portion 320 is disposed on this interposing portion 310. This stepped portion 320 opposes the stepped portion 12. The height of the stepped portion 320 increments with separation from the memory cell array. These interposing portion 310 and stepped portion 320 are formed by cutting the interposing portion 310A and the stepped portion 320A, which are illustrated in FIG. 5, along the dicing line DL.

The stepped portion 320 is disposed on the interposing portion 310. Accordingly, the lowest surface of the stepped portion 320 is formed at a position higher than the lowest surface of the stepped portion 12 of the memory cell array 1. The stepped portion 320 is also formed at a position higher than the conducting layer 102 at the lowest layer of the stepped portion 12. By the volume of this interposing portion 310, a count of first insulating layers 321 included in the stepped portion 320 is less than the count of the conducting layers 102 included in the stepped portion 12. In this exemplary diagram, the count of the formers is less than the count of the latter by three; however this is merely an example. It is needless to say that the count is not limited to this value.

As illustrated in FIG. 9A, the interposing portion 310 includes an insulating layer 311, a polysilicon layer 312, and a metal layer 313, which are laminated on the substrate 101. These insulating layer 311, polysilicon layer 312, and metal layer 313 are each made of materials identical to the gate insulating layer 201, the gate polysilicon layer 202, and the gate metal layer 203 of the transistor Tr and have a film thickness equivalent to these layers. That is, the laminated body having identical structure as the gate electrode layer of the transistor Tr is formed between the stepped portion 320 and the substrate 101.

As illustrated in FIG. 9A, the stepped portion 320 includes the plurality of first insulating layers 321 and second insulating layers 322. The first insulating layers 321 and the second insulating layers 322 are laminated in alternation on the upper portion of the interposing portion 310. These plurality of first insulating layers 321 and second insulating layers 322 are formed into the stepped pattern. The width W2 of one step of these steps in the X direction is equivalent to the width W1. The width W1 is the width of the contact portion 102a in the X direction. Similarly, the width H2 of one step of these steps in the Z direction is equivalent to the interval H1. The interval H1 is the interval of the conducting layer 102 in the Z direction. The first insulating layer 321 is, for example, made of oxide silicon (SiO₂). The second insulating layer 322 is, for example, made of silicon nitride (SiN).

In the example illustrated in FIG. 9A, the interposing portion 310 has the identical film structure to the gate electrode of the transistor Tr constituting the peripheral circuit 2. However, for example, the interposing portion 310 can be constituted by, for example, a single-layered insulating layer.

In the example illustrated in FIG. 9A, the stepped portion 320 is constituted of the two kinds of insulating layers as described above. However, the stepped portion 320 may be constituted by laminating the plurality of insulating layers and conducting layers in alternation and forming these layers into the stepped pattern. In this case, the material identical to the conducting layer 102, which functions as the word line WL or a similar line, may be used for these conducting layers. That is, as described later, the stepped portion 320 may be formed in processes identical to the processes of the stepped portion 12.

FIG. 9B is a schematic cross-sectional view illustrating the constitution of a part of the above-described stepped portion 12, and dummy stepped portion 3 of the memory cell array 1. FIG. 9B omits peripheral circuit 2.

As illustrated by dotted line B in FIG. 9B, the width of the interposing portion 310 in the Z direction coincides with the width of portion of the stepped portion 12 facing the interposing portion 310 (two steps in the embodiment). As described above, the width H2 of one step of the stepped portion 320 in the Z direction coincides with the interval H1 of the conducting layer 102 of the stepped portion 12 in the Z direction. Therefore, as illustrate by dotted line A in FIG. 9B, the height of the top surface of the stepped portion 320 coincides with the height of the top surface of the stepped portion 12.

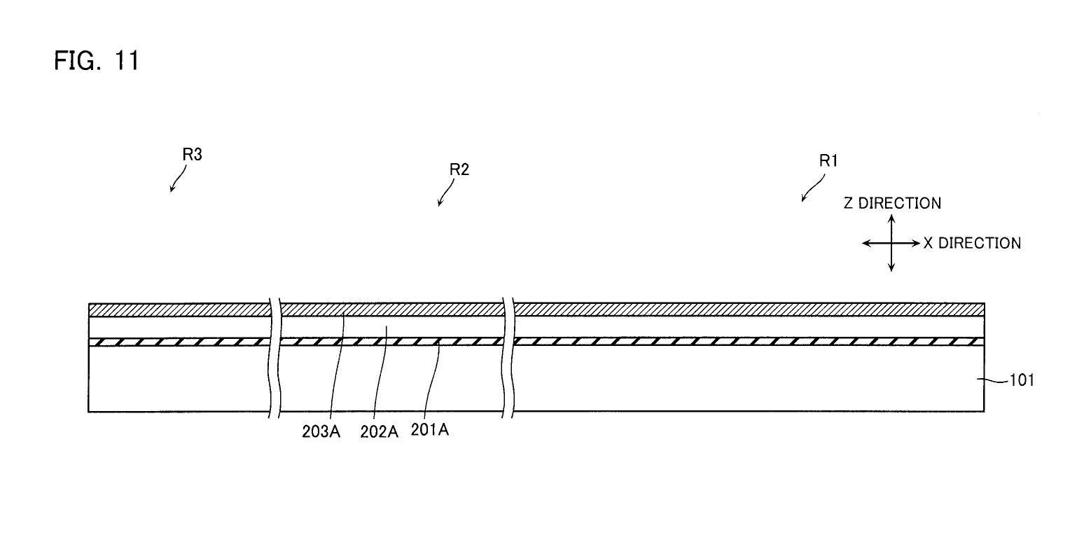

Next, the following describes a method for manufacturing the semiconductor memory device according to the embodiment with reference to FIG. 11 to FIG. 23. FIG. 11 to FIG. 23 are schematic cross-sectional views for describing the manufacturing method.

As illustrated in FIG. 11, an insulating layer 201A, a polysilicon layer 202A, and a metal layer 203A are formed on the wafer 101A, which will be the substrate 101.

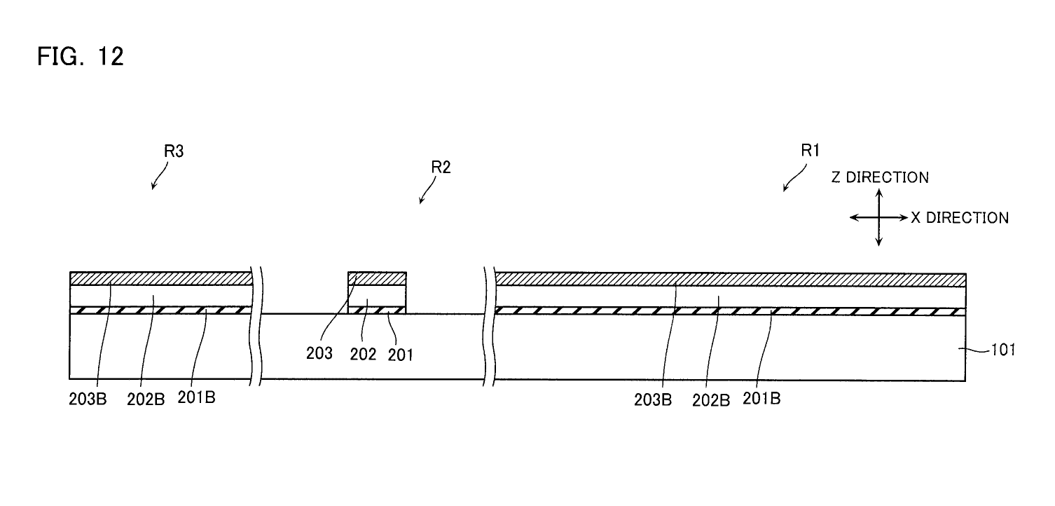

As illustrated in FIG. 12, a part of the gate insulating layer forming layer 201A, the gate polysilicon layer forming layer 202A, and the gate metal layer forming layer 203A are removed. The gate insulating layer 201, the gate polysilicon layer 202, and the gate metal layer 203 as components of the transistor Tr are formed at the peripheral circuit region R2. This process forms an insulating layer 201B, a polysilicon layer 202B, and a metal layer 203B at the memory cell array region R1 and the dummy stepped region R3.

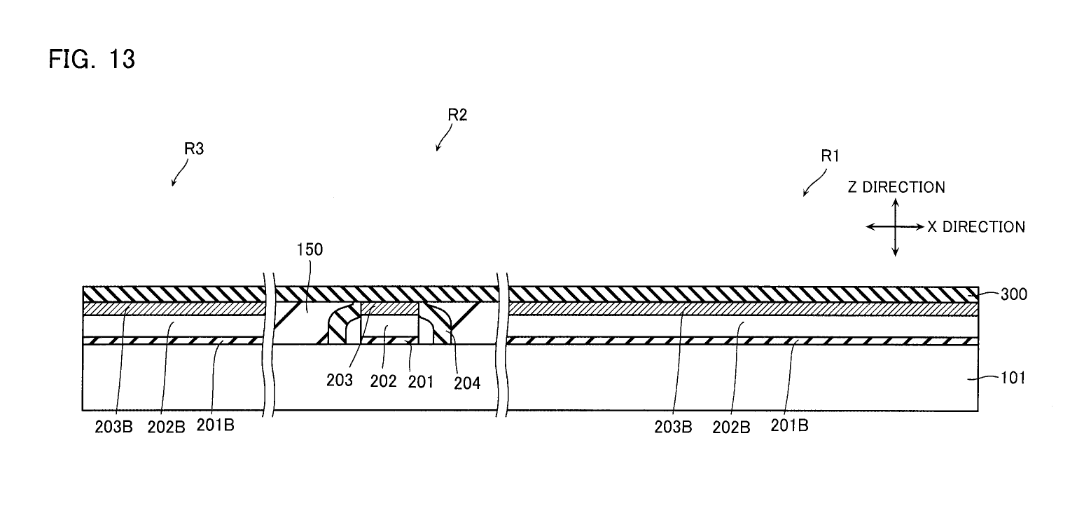

As illustrated in FIG. 13, the barrier layer 204 is formed. The barrier layer 204 covers the side surfaces of the gate insulating layer 201, the gate polysilicon layer 202, and the gate metal layer 203 at the peripheral circuit region R2. Then, a barrier layer 300 made of silicon nitride is formed. The barrier layer 300 is formed so as to cover the entire top surface of the respective regions R1, R2, and R3. An oxide film 150 is embedded in the peripheral circuit region R2.

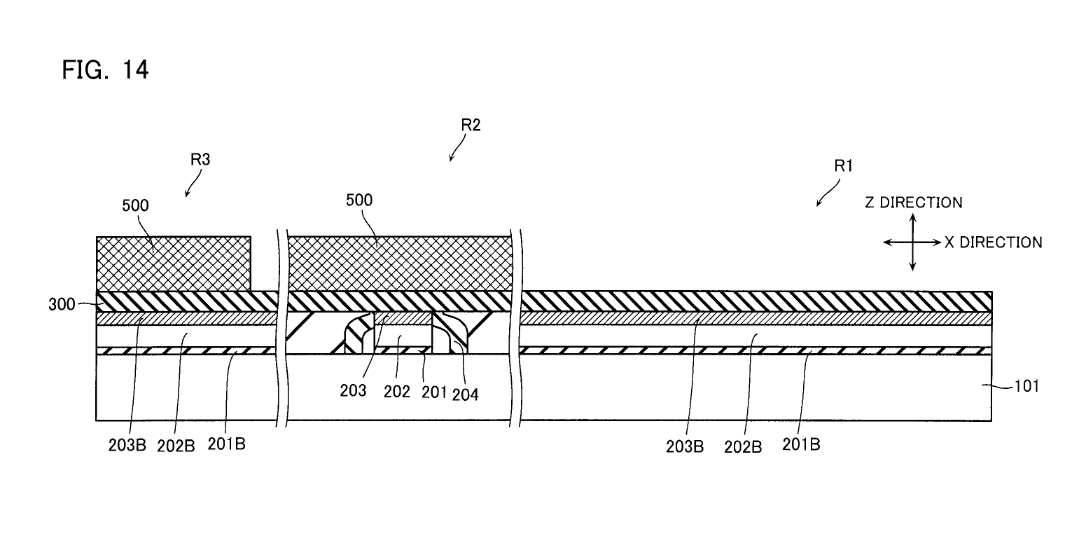

As illustrated in FIG. 14, resists 500 that cover a part of the dummy stepped region R3 and the entire surface of the peripheral circuit region R2 are formed.

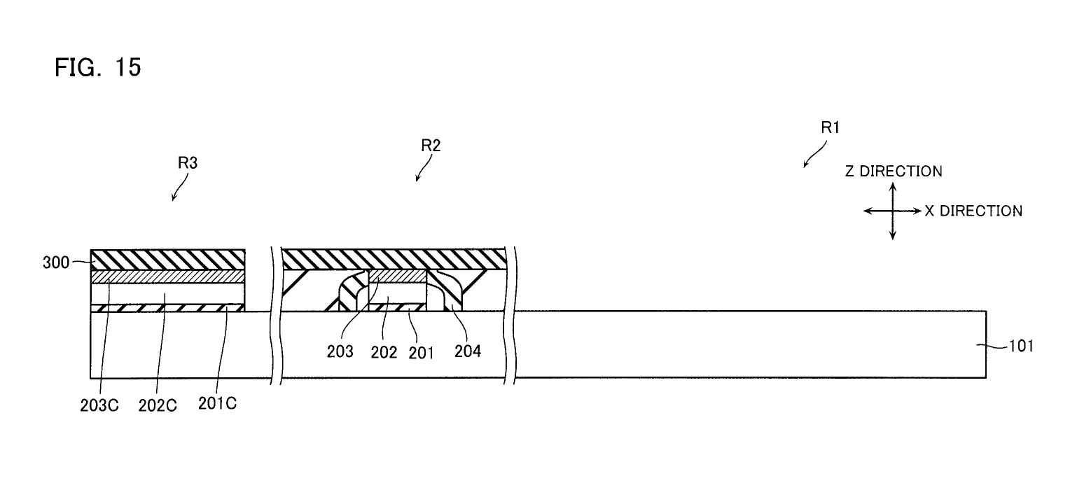

As illustrated in FIG. 15, masking the resists 500, all the insulating layer 201B, the polysilicon layer 202B, the metal layer 203B, and the barrier layer 300 at the memory cell array region R1 and a part of the insulating layer 201 B, the polysilicon layer 202B, the metal layer 203B, and the barrier layer 300 at the dummy stepped region R3 are removed. This removes all the insulating layer 201B, the polysilicon layer 202B, the metal layer 203B, and the barrier layer 300 at the memory cell array region R1.

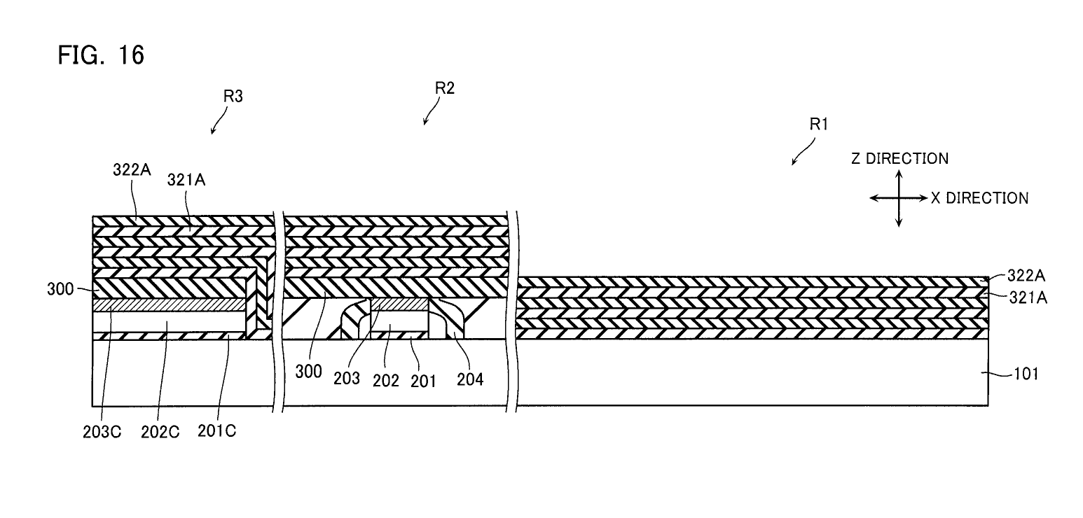

As illustrated in FIG. 16, a plurality of insulating layers 321A and insulating layers 322A are laminated in alternation.

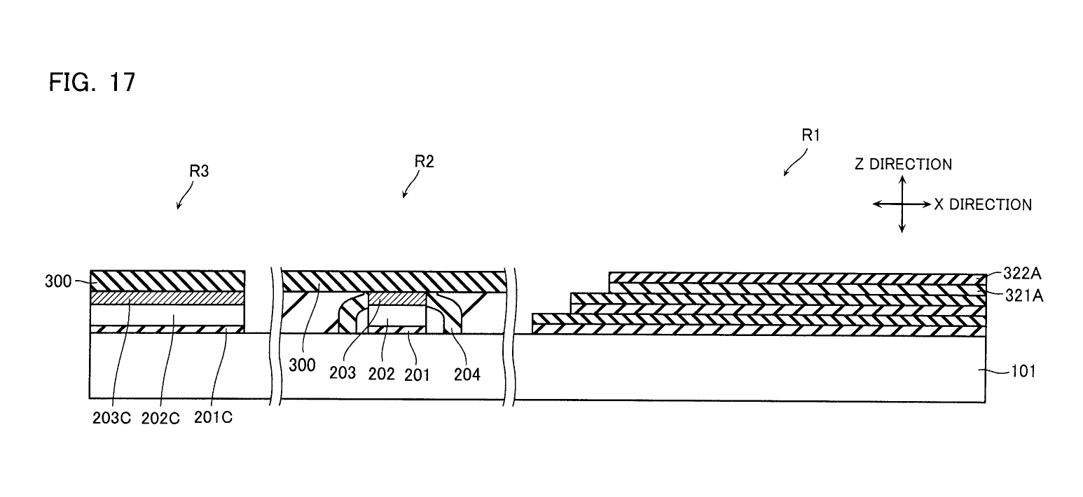

Afterwards, a resist (not illustrated) is deposited on the top surface of the insulating layers 321A and the insulating layers 322A at the memory cell array region R1. While slimming this resist gradually, the insulating layers 321A and the insulating layers 322A at the memory cell array region R1 are etched. In view of this, as illustrated in FIG. 17, the stepped structure of the insulating layers 321A and the insulating layers 322A whose width in the X direction is W1 and the height of the level difference in the Z direction is H1 is formed at the memory cell array region R1. The insulating layers 321A and 322A at the regions R2 and R3 are all removed. Thus, the above-described insulating layer 321A becomes the insulating layer 103.

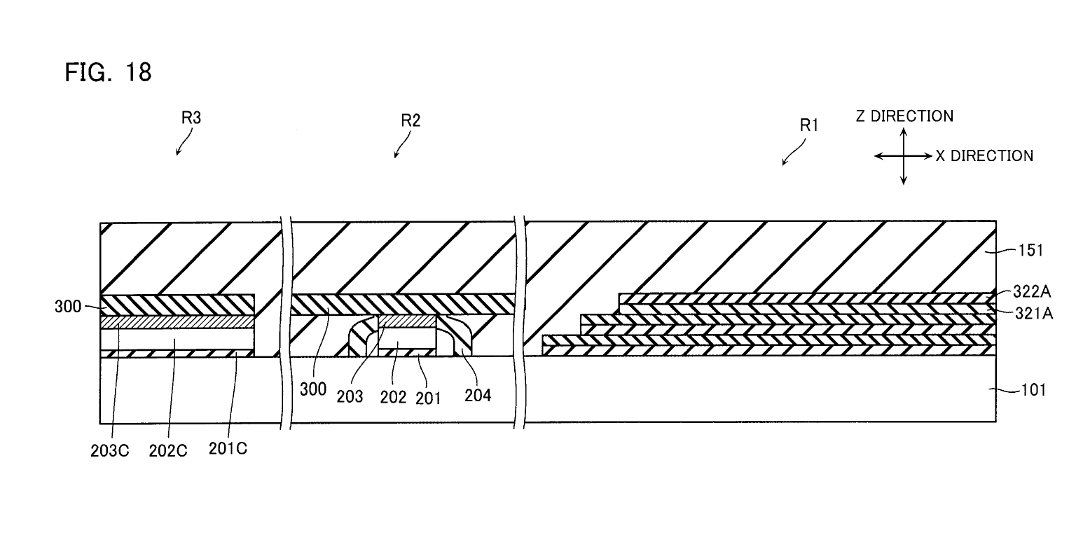

As illustrated in FIG. 18, insulating films 151 such as oxide silicon are deposited so as to cover the entire surfaces of the regions R1, R2, and R3.

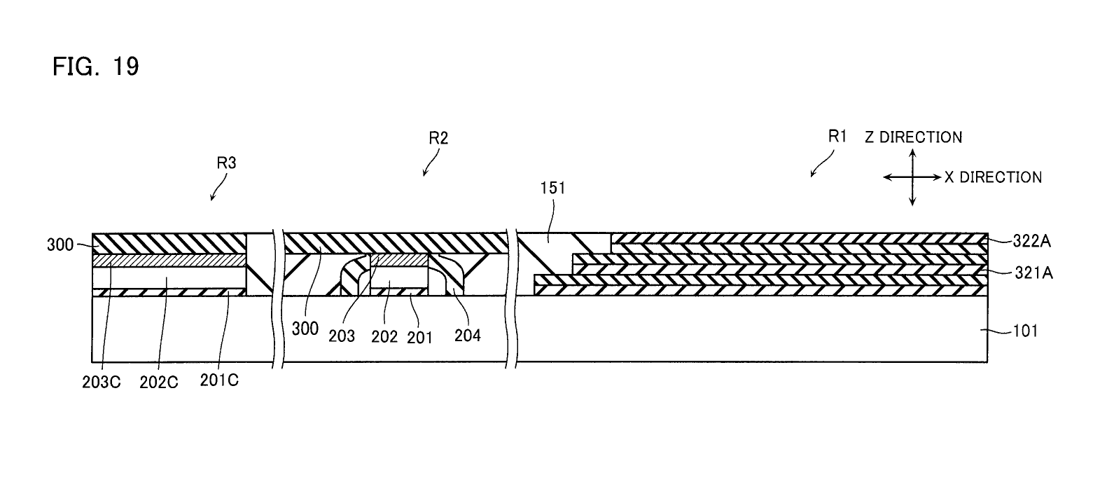

As illustrated in FIG. 19, using barrier layers 300 as a stopper, the regions are each flattened. The order of the processes described in FIG. 12 and FIG. 13 may be reversed. That is, from the state illustrated in FIG. 11, the regions may be flattened using the barrier layers 300 as the stopper, and then the insulating film 151 may be deposited.

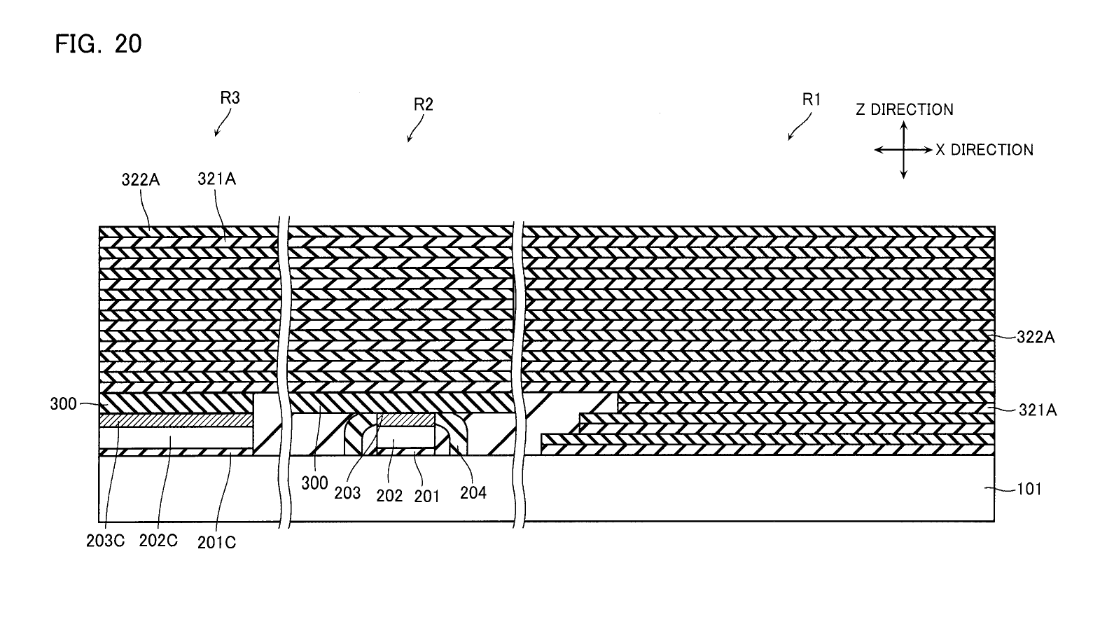

As illustrated in FIG. 20, the plurality of insulating layers 321A and insulating layers 322A are laminated in alternation again.

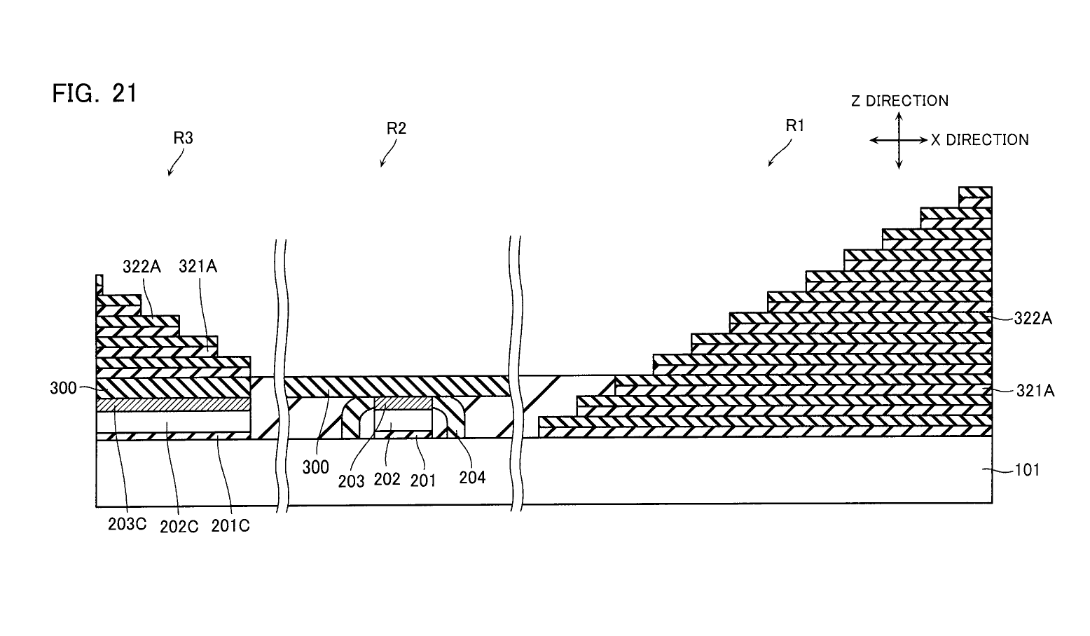

Afterwards, the resist (not illustrated) is deposited on the top surface of the insulating layers 321A and the insulating layers 322A at the memory cell array region R1. While slimming this resist gradually, the insulating layers 321A and the insulating layers 322A are etched. In view of this, as illustrated in FIG. 21, the insulating layer 321A and the insulating layer 322A positioned on the upper side more than the barrier layer 300 at the memory cell array region R1 and the dummy stepped region R3 are processed into the stepped pattern through the process similar to the process described in FIG. 17. Accordingly, at the memory cell array region R1 and the dummy stepped region R3, the stepped structures of the insulating layers 321A and the insulating layers 322A whose width and height of the level difference are approximately identical are formed.

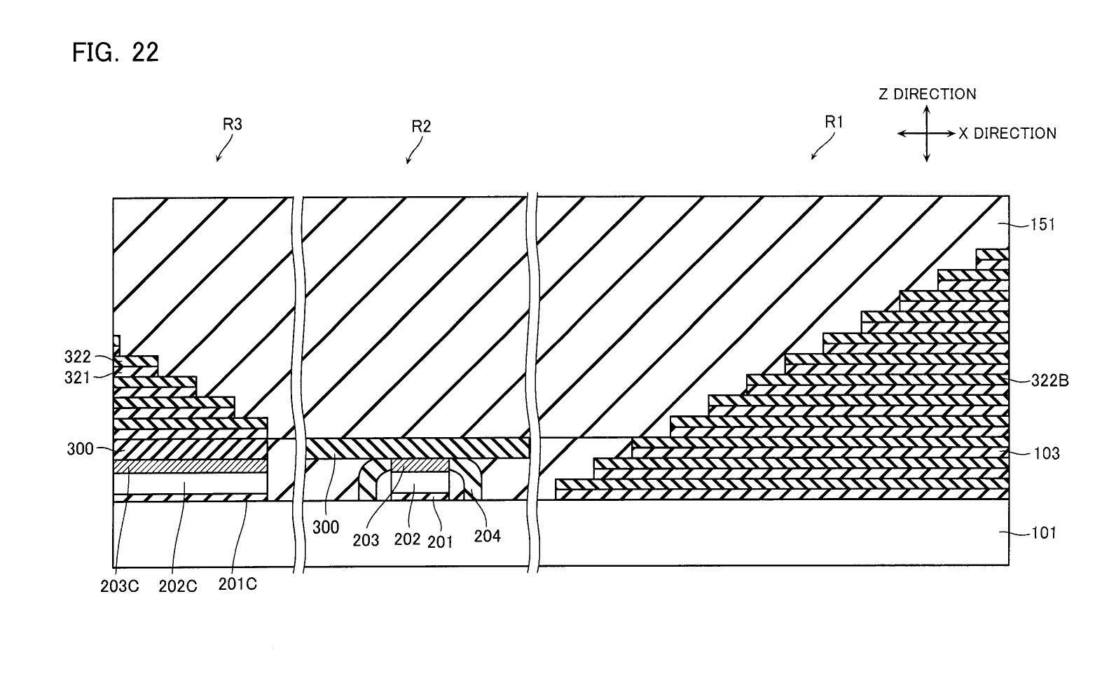

As illustrated in FIG. 22, the insulating films 151 such as oxide silicon are deposited so as to cover the entire surfaces of the regions R1, R2, and R3.

Then, the insulating layers 322B are removed at the memory cell array region R1, and the conducting layers 102 are formed here. In this respect, on the dummy stepped region R3, the above-described processes of removing the insulating layers and forming the conducting layers are not performed. The plurality of via contact wirings 109, the source contact via wiring 207, and the drain contact via wiring 208; and the conducting layers 106 (bit lines BL) and the conducting layer 107 (source line SL), which are described with reference to FIG. 8, and a similar layer are formed. This manufactures the wafer 101A (see FIG. 2). Further, the wafer 101A is separated along the dicing lines DL (see FIG. 2), thus manufacturing the plurality of semiconductor memory devices.

### Second Embodiment

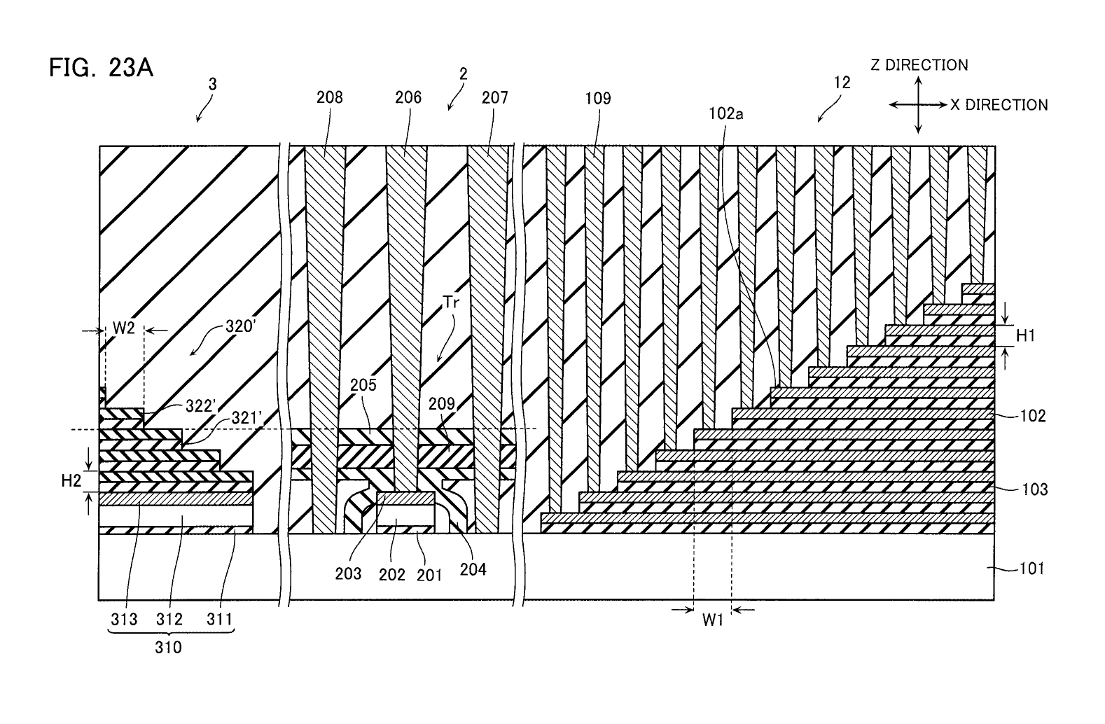

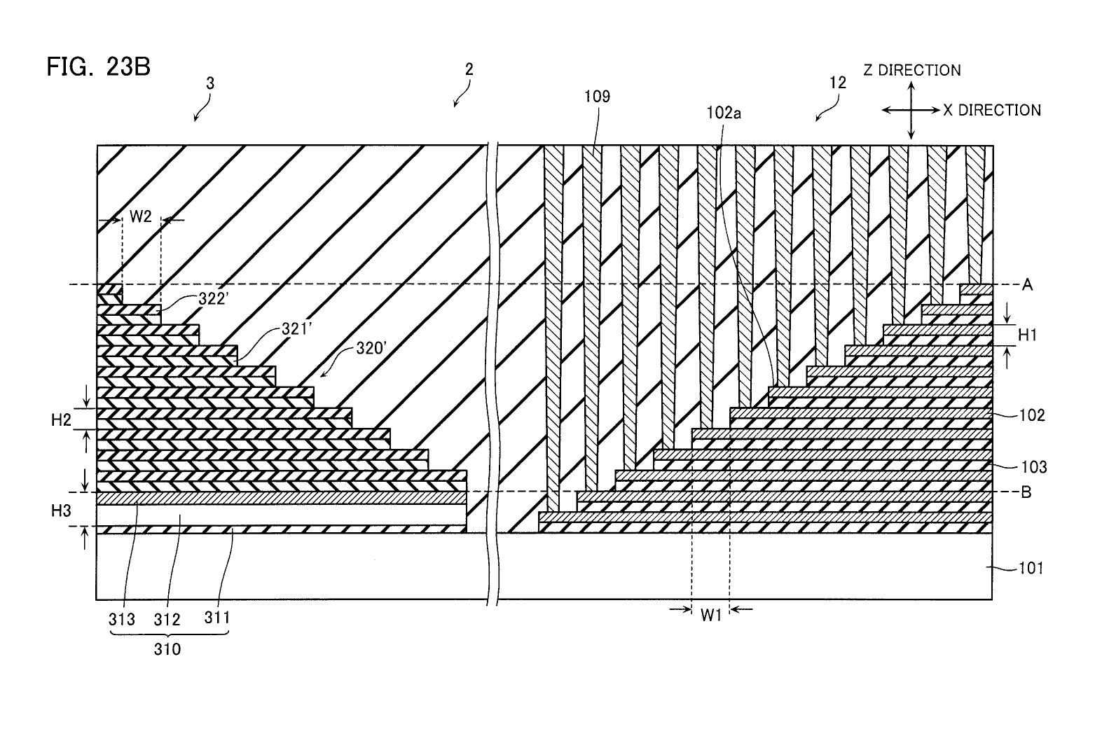

Next, with reference to FIGS. 23A and 23B, the following describes the constitution of the semiconductor memory device according to the second embodiment. FIG. 23 is a schematic cross-sectional view illustrating the constitution of the semiconductor memory device according to the second embodiment. FIG. 20 omits a part of the constitution. The constitution illustrated in FIG. 23 is merely an example. The detailed constitution or a similar constitution can be changed as necessary.

As illustrated in FIG. 23A, the semiconductor memory device is basically similarly constituted to the semiconductor memory device according to the first embodiment. However, according to the embodiment, a barrier layer 205 is further disposed above the barrier layer 204 of the transistor Tr. The height of the top surface of the barrier layer 205 (position in the Z direction) and the height of the lower surface of a predetermined first insulating layer 321′ approximately match. In this respect, the second embodiment differs from the first embodiment. This drawing illustrates the constitution where the height of the top surface of the barrier layer 205 matches the height of the lower surface of the predetermined first insulating layer 321′. However, the height of the top surface of the barrier layer 205 may match the height of the lower surface of a predetermined second insulating layer 322′.

With the semiconductor memory devices illustrated in FIG. 23A, as details are described later, a production cost can be saved.

FIG. 23B is a schematic cross-sectional view illustrating the constitution of a part of the above-described stepped portion 12, and dummy stepped portion 3 of the memory cell array 1. FIG. 23B omits peripheral circuit 2.

As illustrated by dotted line B in FIG. 23B, the width of the interposing portion 310 in the Z direction coincides with the width of portion of the stepped portion 12 facing the interposing portion 310 (two steps in the embodiment). As described above, the width H2 of one step of the stepped portion 320′ in the Z direction coincides with the interval H1 of the conducting layer 102 of the stepped portion 12 in the Z direction. Therefore, as illustrate by dotted line A in FIG. 23B, the height of the top surface of the stepped portion 320′ coincides with the height of the top surface of the stepped portion 12.

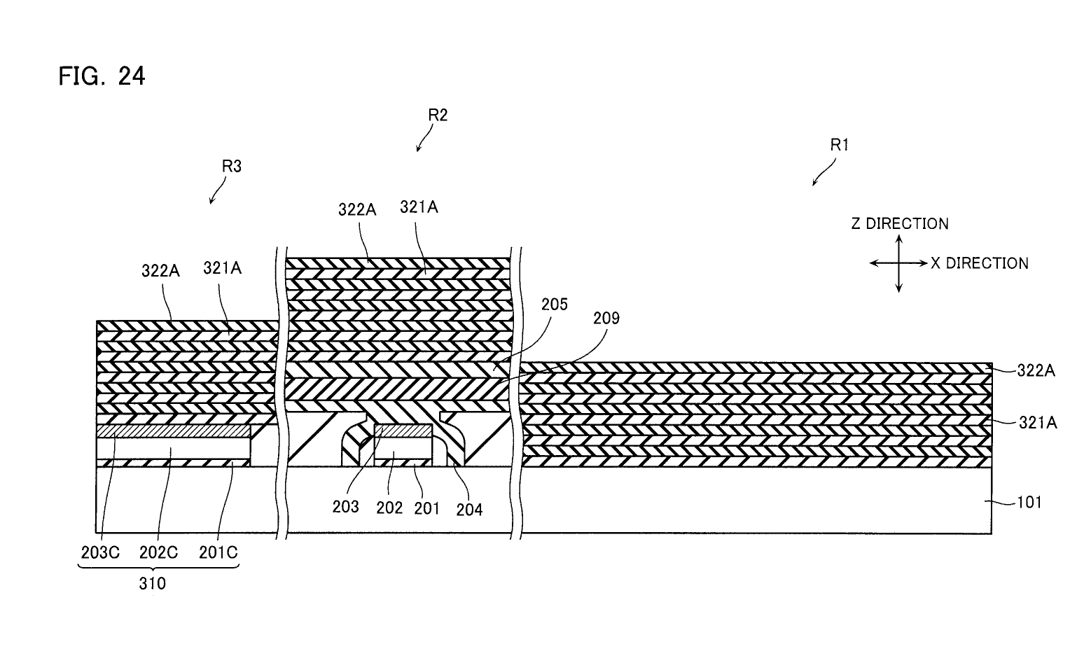

Next, the following describes the method for manufacturing the semiconductor memory device according to the embodiment with reference to FIG. 24 to FIG. 28. FIG. 24 to FIG. 28 are schematic cross-sectional views for describing the manufacturing method.

The manufacturing method according to the embodiment performs the processes of the first embodiment described with reference to FIG. 11 to FIG. 15. However, in this respect, at the transistor Tr, a second barrier layer 205 as a stopper material for a flattening process, which will be described later, is formed above the barrier layer 204 via an insulating layer 209.

As illustrated in FIG. 24, the plurality of insulating layers 321A and insulating layers 322A are laminated in alternation. With this process, the insulating layers 321A and the insulating layers 322A are laminated until becoming a height similar to the barrier layer 205.

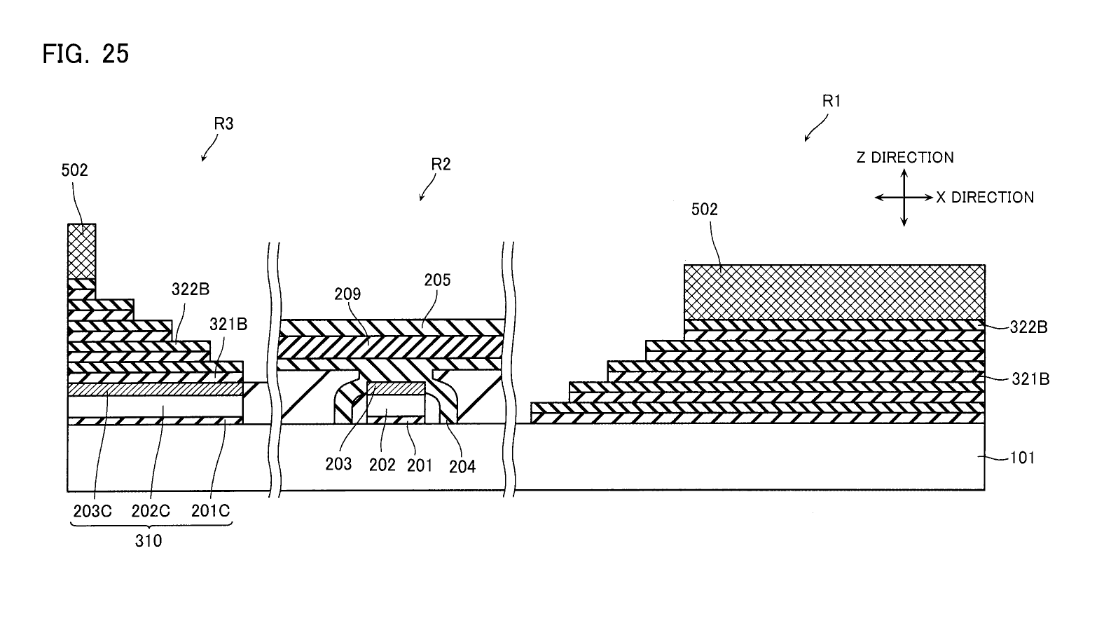

As illustrated in FIG. 25, resists 502 are formed on the top surfaces of the insulating layers 321A and the insulating layers 322A. Further, the resists 502 are removed by the above-described width W1 in the X direction. Whenever the resist 502 is removed, the insulating layer 321A and the insulating layer 322A are removed by one layer. This forms the stepped structures whose width in the X direction is W1 and the level difference in the Z direction is H1 at the memory cell array region R1 and the dummy stepped region R3. This process forms the insulating layers 321B and the insulating layers 322B at the dummy stepped region R3.

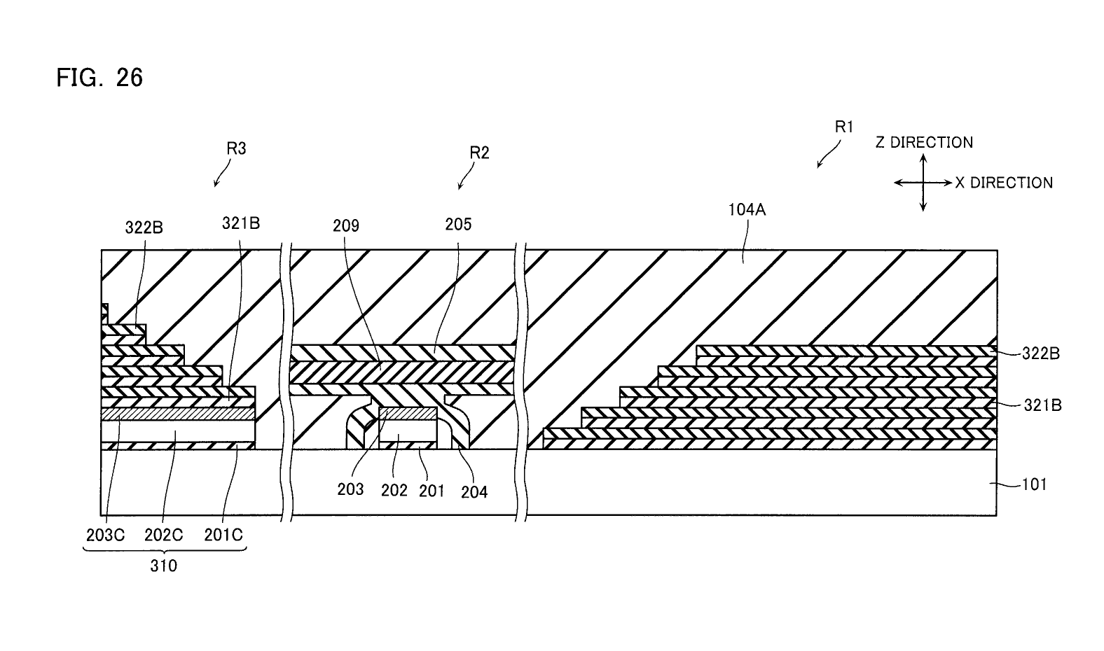

As illustrated in FIG. 26, the resists 502 are removed and insulating layers 104A are embedded in all the regions. The insulating layer 104A is, for example, made of oxide silicon (SiO₂).

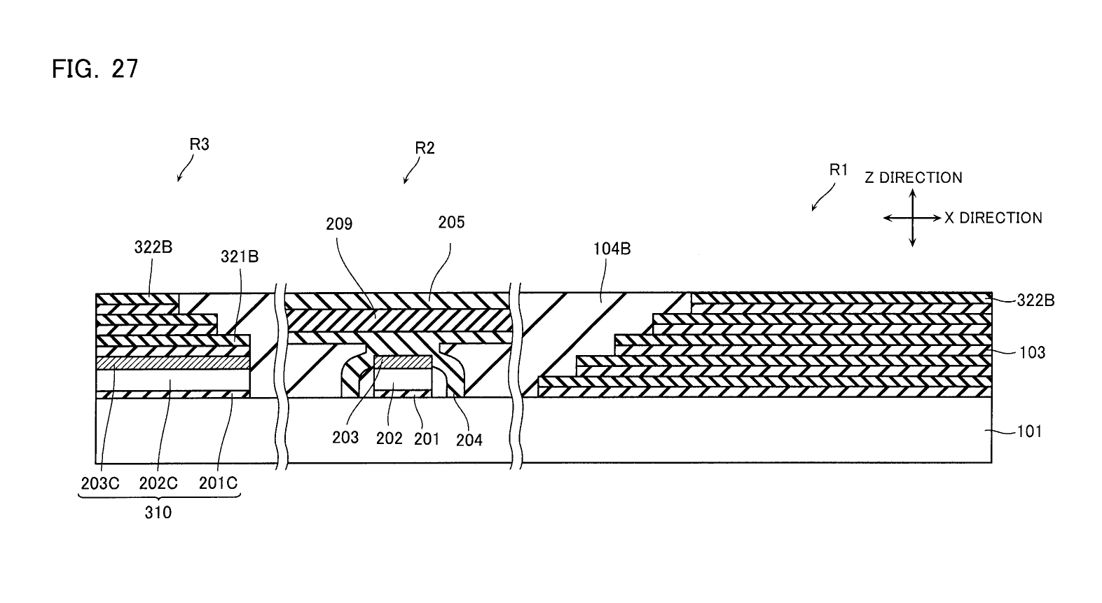

As illustrated in FIG. 27, using the barrier layer 205 as a stopper, the flattening process such as Chemical Mechanical Polishing (CMP) is performed, thus removing a part of the insulating layers 104A. This forms insulating layers 104B. This process also removes a part of the plurality of insulating layers 321B and insulating layers 322B positioned at the peripheral circuit region R2 and the dummy stepped region R3. Specifically, the parts positioned above the barrier layer 205 of the transistor Tr are removed. At this point, the insulating layers 321B and the insulating layers 322B become the first insulating layers 321 and the second insulating layers 322, forming a part of the stepped portion 320.

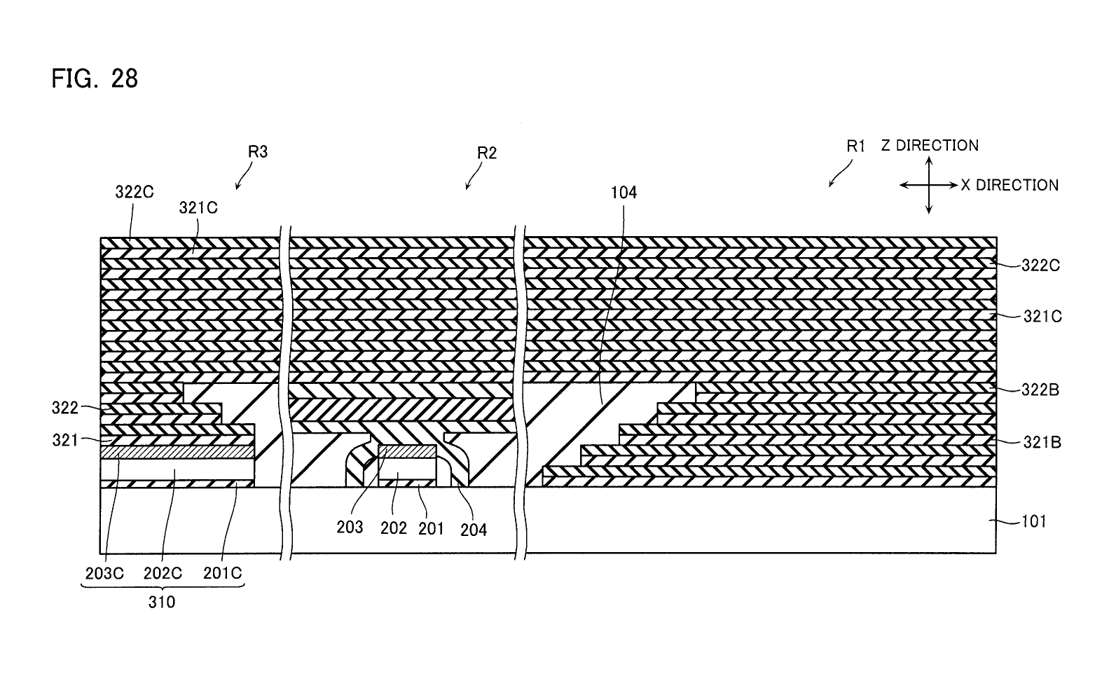

As illustrated in FIG. 28, a plurality of insulating layers 321C and insulating layers 322C are further laminated. As illustrated in FIG. 28, these plurality of insulating layers 321C and insulating layers 322C are formed flat at the memory cell array region R1, the peripheral circuit region R2, and the dummy stepped region R3. The insulating layer 321C is, for example, made of oxide silicon (SiO₂) and becomes the insulating layer 103. The insulating layer 322C is, for example, made of silicon nitride (SiN) and removed during the manufacturing process.

Then, for example, the process similar to the process described with reference to FIG. 21 is performed. The plurality of insulating layers 321C and insulating layers 322C are formed in the stepped pattern at the memory cell array region R1 and the dummy stepped region R3. The plurality of insulating layers 321C and insulating layers 322C are removed at the peripheral circuit region R2.

For example, the processes similar to the processes described with reference to FIG. 22 and FIG. 23 are performed. The insulating layer 322C is removed at the memory cell array region R1 and the conducting layer 102 is formed here. The plurality of via contact wirings 109, the source contact via wiring 207, and the drain contact via wiring 208; and the conducting layers 106 (bit lines BL) and the conducting layer 107 (source line SL), which are described with reference to FIG. 8, and a similar layer are formed. This manufactures the wafer according to the embodiment. Further, this wafer is separated along the dicing lines DL, thus manufacturing the plurality of semiconductor memory devices according to the embodiment.

The manufacturing method according to the embodiment, as described with reference to FIG. 24 to FIG. 28, the insulating layers 321A and the insulating layers 322A are formed into the stepped pattern at the upper portion of the interposing portion 310, and the flattening process is performed. Further, the insulating layers 321C and the insulating layers 322C are laminated, and these layers are formed into the stepped pattern. Accordingly, the step count of the steps of a stepped portion 320A in a kerf portion 3A can be less than the step count of the stepped portion 12 at the memory cell block MB. This allows reducing the width of the kerf portion 3A′ in the X direction. This allows increasing the count of the semiconductor memory devices manufactured from one wafer 101A , also allowing saving a bit cost.

[Modification]

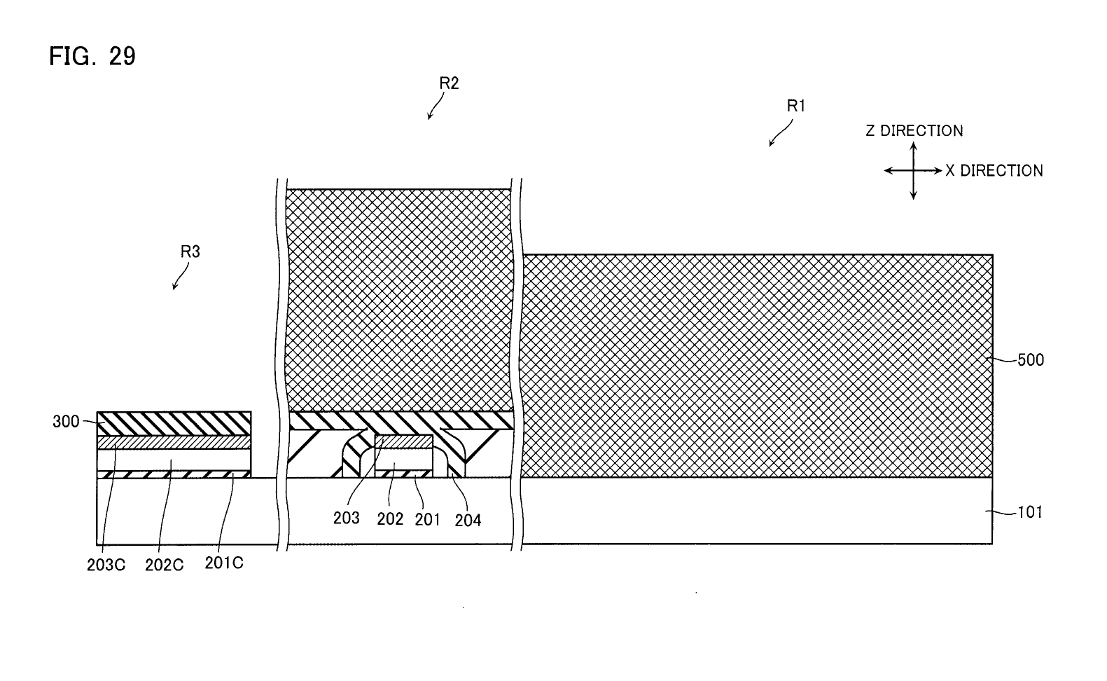

The following describes some modifications with reference to FIG. 29 to FIG. 37.

In the state of FIG. 15 of the first embodiment, as illustrated in FIG. 29, resists 500 may be formed so as to cover the entire surfaces of the memory cell array region R1 and the peripheral circuit region R2. Etching may remove the barrier layer 300 at the dummy stepped region R3.

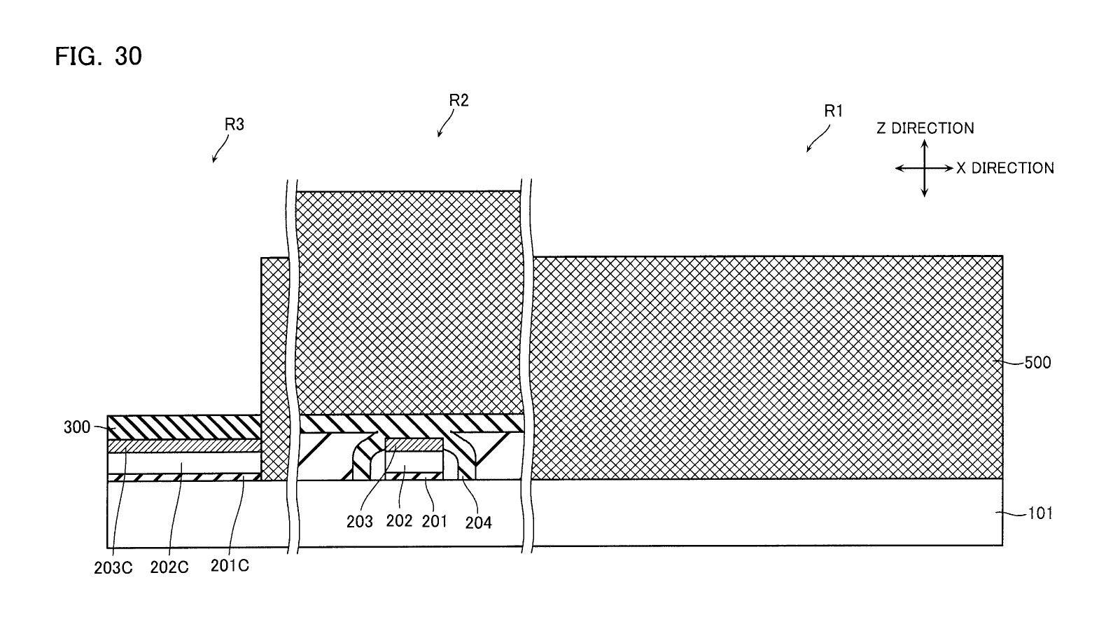

In this respect, as illustrated in FIG. 30, when disposing the resist 500 also at a part of the dummy stepped region R3, this protects the substrate 101 against a liquid medicine treatment or a similar treatment to remove the barrier layer 300 at the dummy stepped region R3.

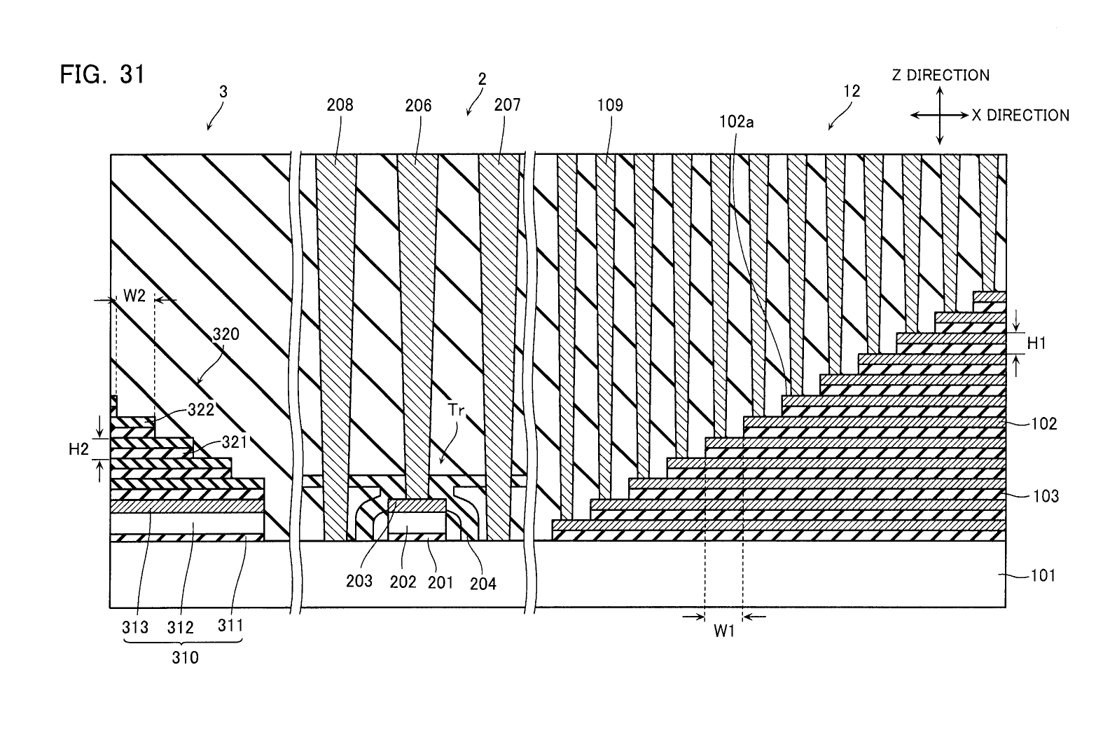

Through the above-described processes in FIG. 29 and FIG. 30, the semiconductor memory device with the constitution illustrated in FIG. 31 is obtained.

The resists 500 can also be disposed at positions other than the positions illustrated in FIG. 29 and FIG. 30.

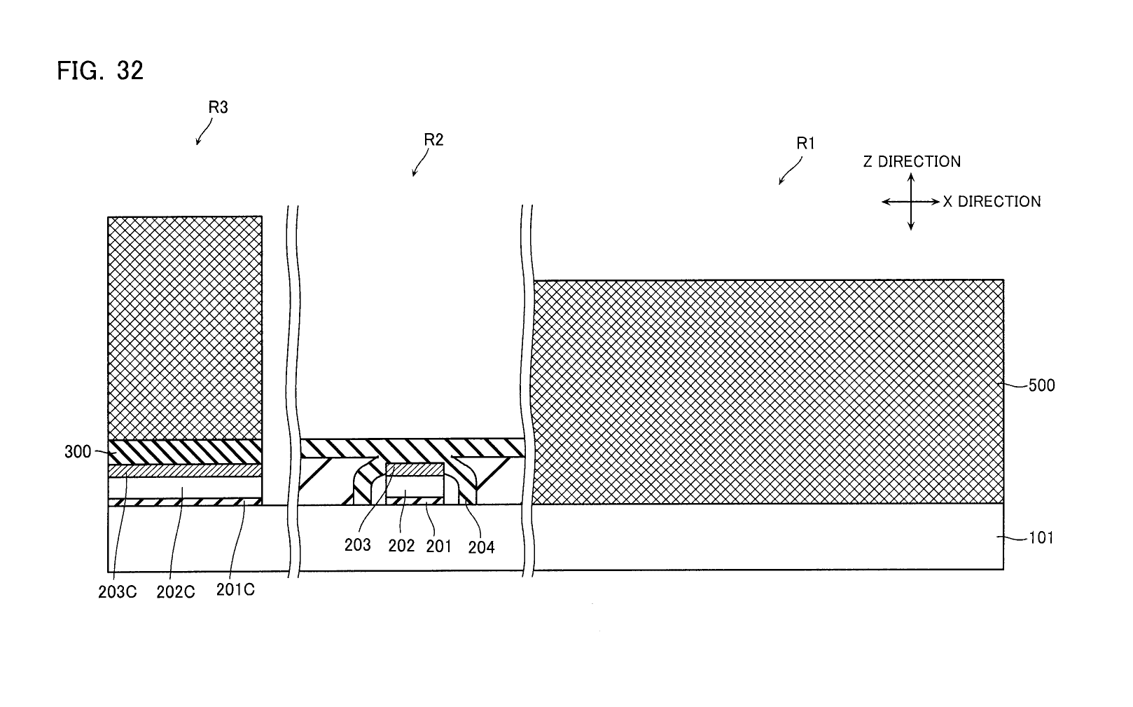

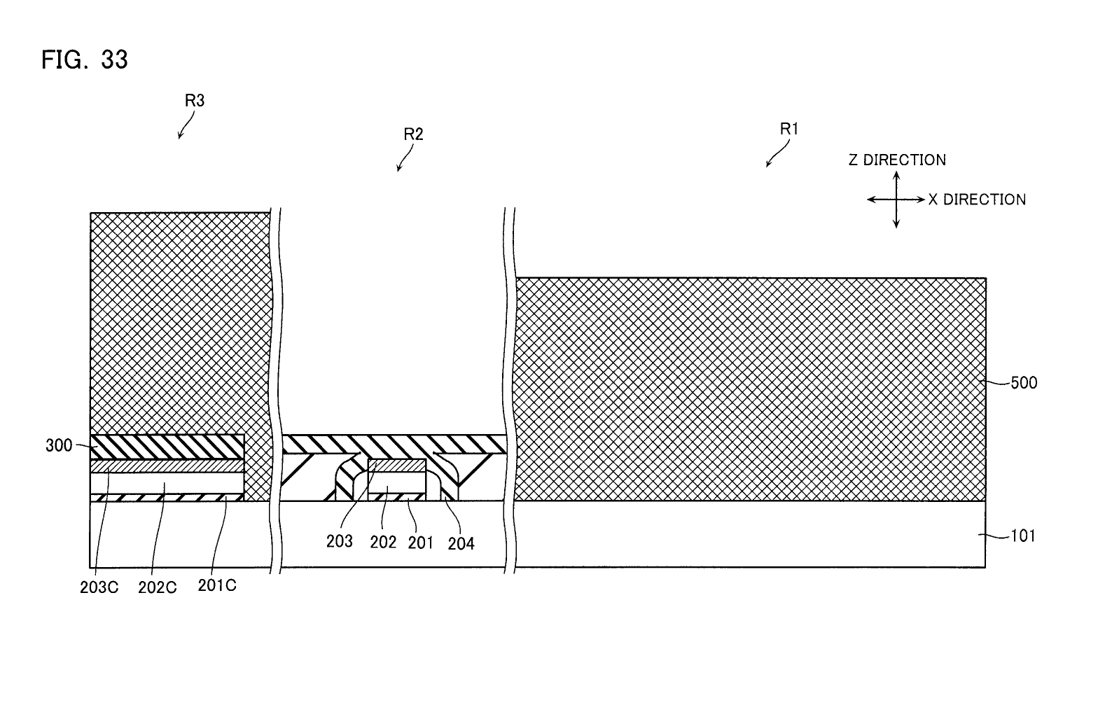

As illustrated in FIG. 32 and FIG. 33, the resists 500 may be disposed so as to cover the entire surface of the memory cell array region R1 and the entire surface or a part of the dummy stepped region R3. The etching may remove the barrier layer 300 at the peripheral circuit region R2.

In this respect as well, as illustrated in FIG. 33, when disposing the resist 500 at the entire surface of the dummy stepped region R3, this protects the substrate 101 against the liquid medicine treatment or a similar treatment to remove the barrier layer 300 at the peripheral circuit region R2.

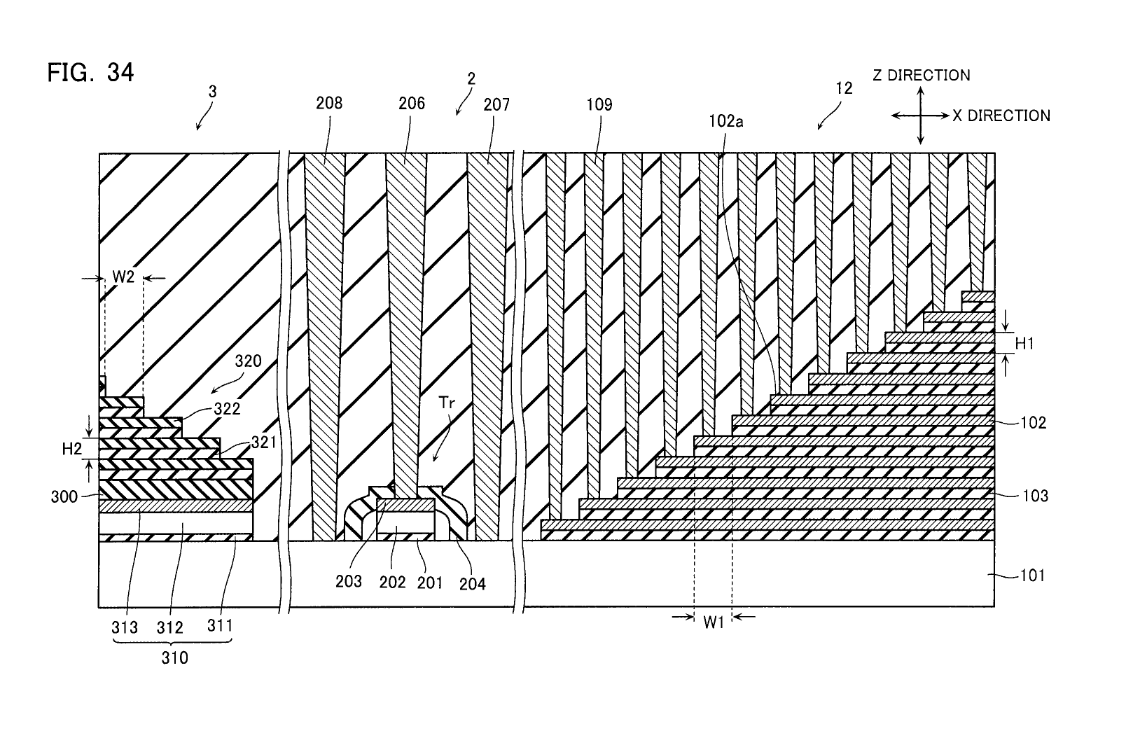

Through the above-described processes in FIG. 32 and FIG. 33, the semiconductor memory device with the constitution illustrated in FIG. 34 is obtained.

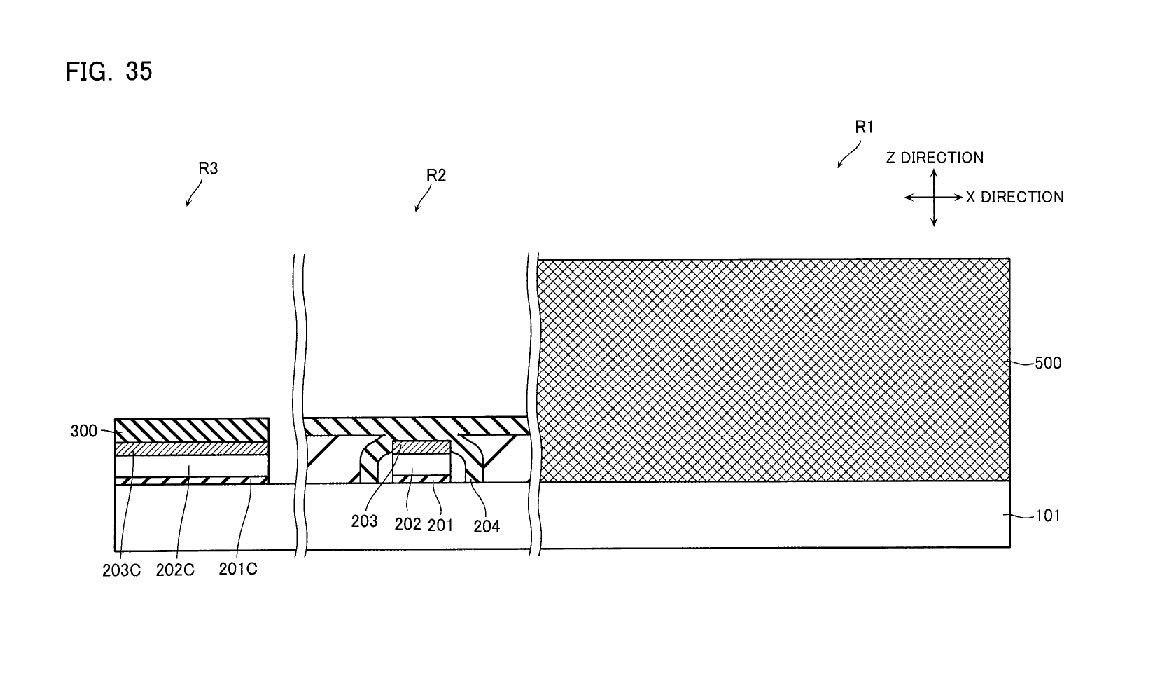

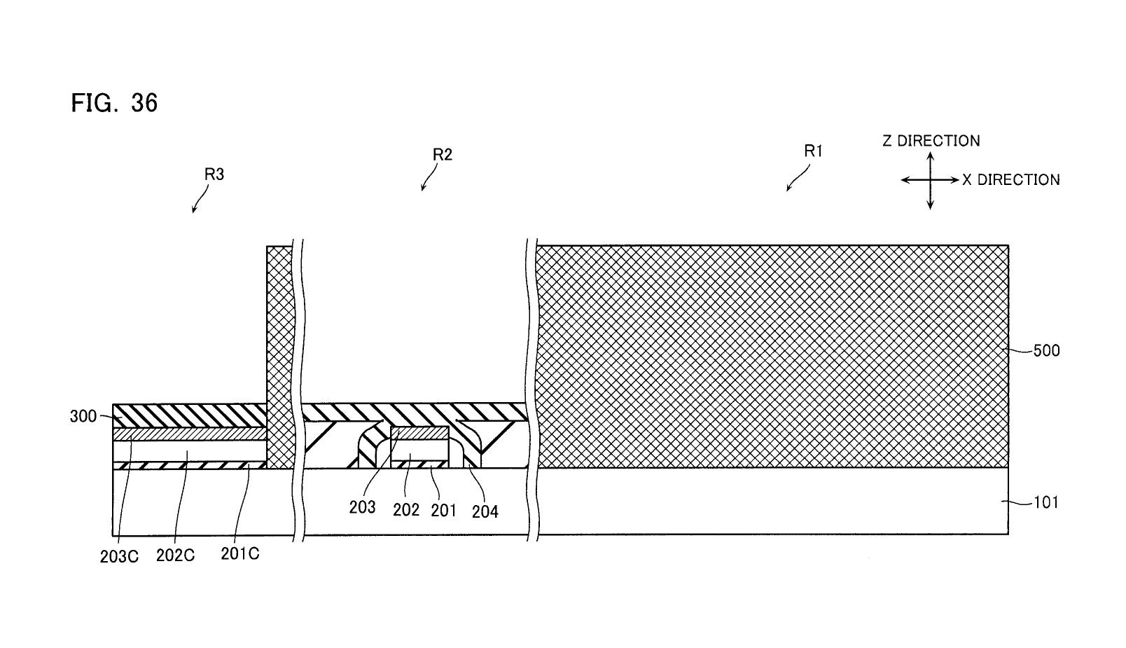

As illustrated in FIG. 35 and FIG. 36, the resist 500 may be disposed so as to cover the entire surface at the memory cell array region R1 or the entire surface at the memory cell array region R1 and a part of the dummy stepped region R3.

In this respect as well, as illustrated in FIG. 36, when disposing the resist 500 at the region where the barrier layer 300 is not disposed at the dummy stepped region R3, this protects the substrate 101 against the liquid medicine treatment or a similar treatment to remove the barrier layer 300 at the peripheral circuit region R2 and the dummy stepped region R3.

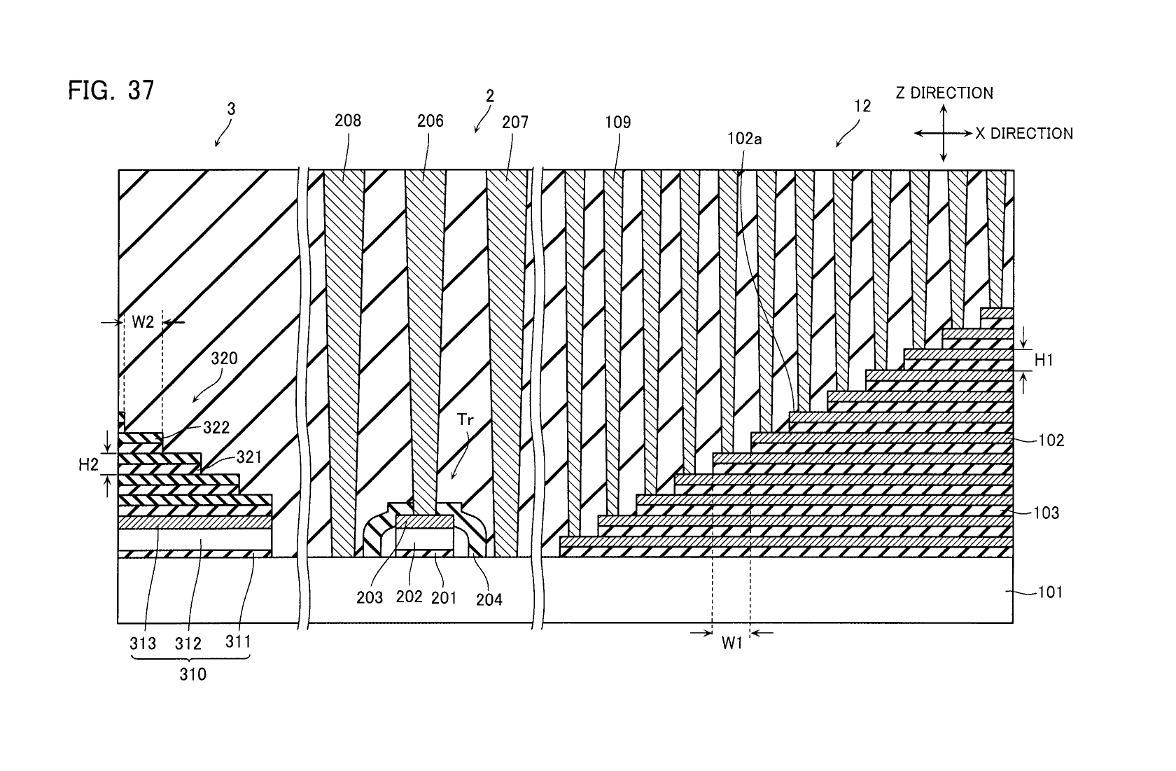

Through the above-described processes in FIG. 35 and FIG. 36, the semiconductor memory device with the constitution illustrated in FIG. 37 is obtained.

Like the above-described modifications, the addition of the processes of the arrangement of the resists 500 and the etching allows adjusting the presence/absence of the barrier layer 300 at the peripheral circuit region R2 or the dummy stepped region R3. This allows adjusting the height of the level difference at the dummy stepped portion 3 and reducing hydrogen radical emitted from the silicon nitride, which constitutes the barrier layer 300. Accordingly, an improvement in cell properties can be expected.

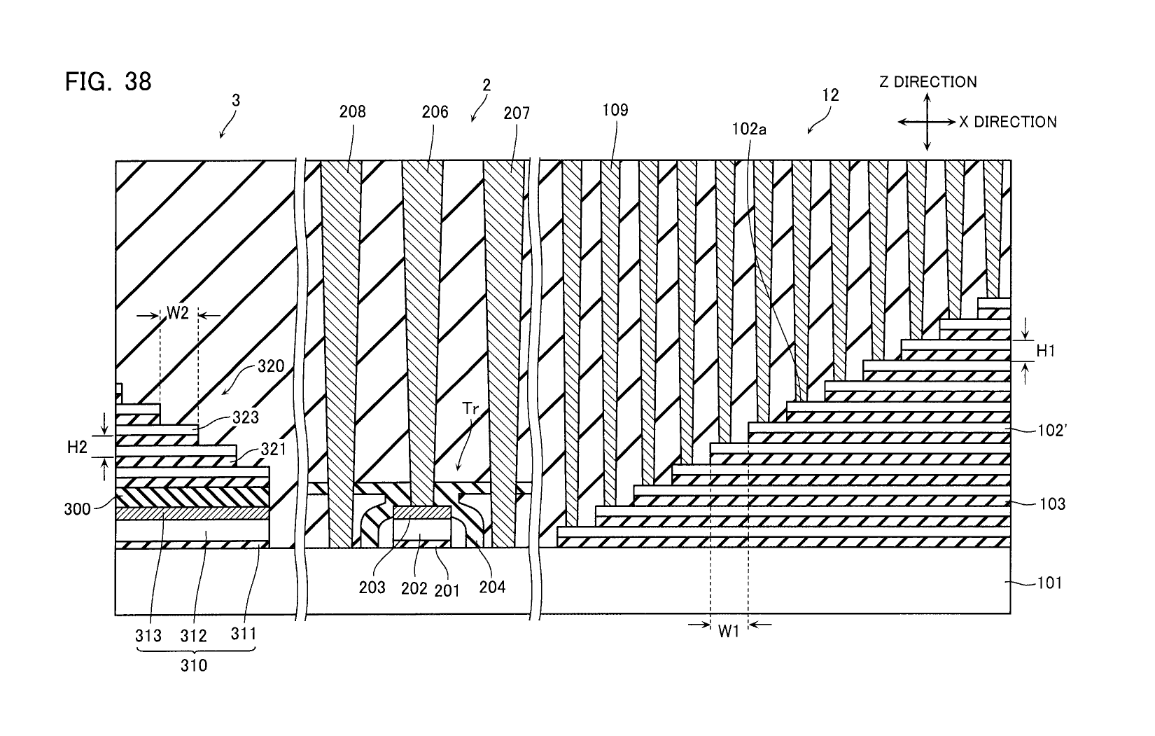

FIG. 38 shows an example of the memory cell array according to yet another embodiment. As illustrated in FIG. 38, the semiconductor memory device is basically similarly constituted to the semiconductor memory device according to the first embodiment. However, according to the embodiment, the constitution of the conducting layer of the stepped portion 12 and the one insulating layer of the stepped portion are different from the first embodiment. That is, in the embodiment, the stepped portion has the constitution in which the insulating layer 103 and the conducting layer 102′ are laminated in alternation on the substrate 101. The semiconductor layer 102′ is made of the semiconductor such as polysilicon. On the other hand, the stepped portion has the constitution in which the insulating layer 321 and the semiconductor layer 323. The semiconductor layer is made of the semiconductor such as polysilicon, and the same as the semiconductor layer 102′ in the stepped portion 12.

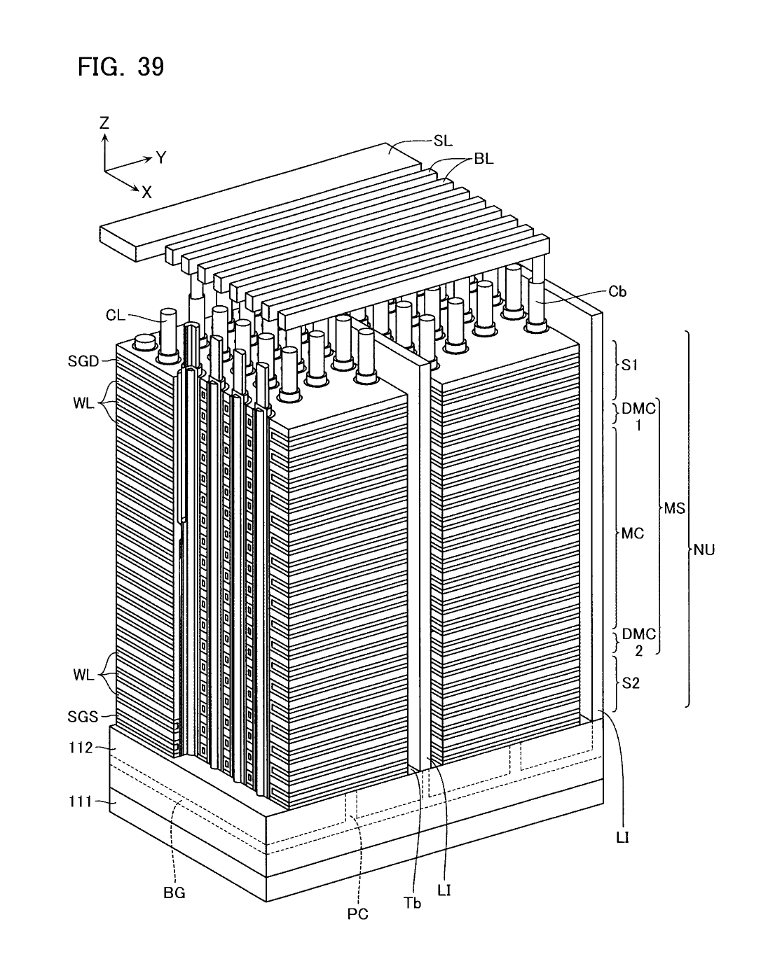

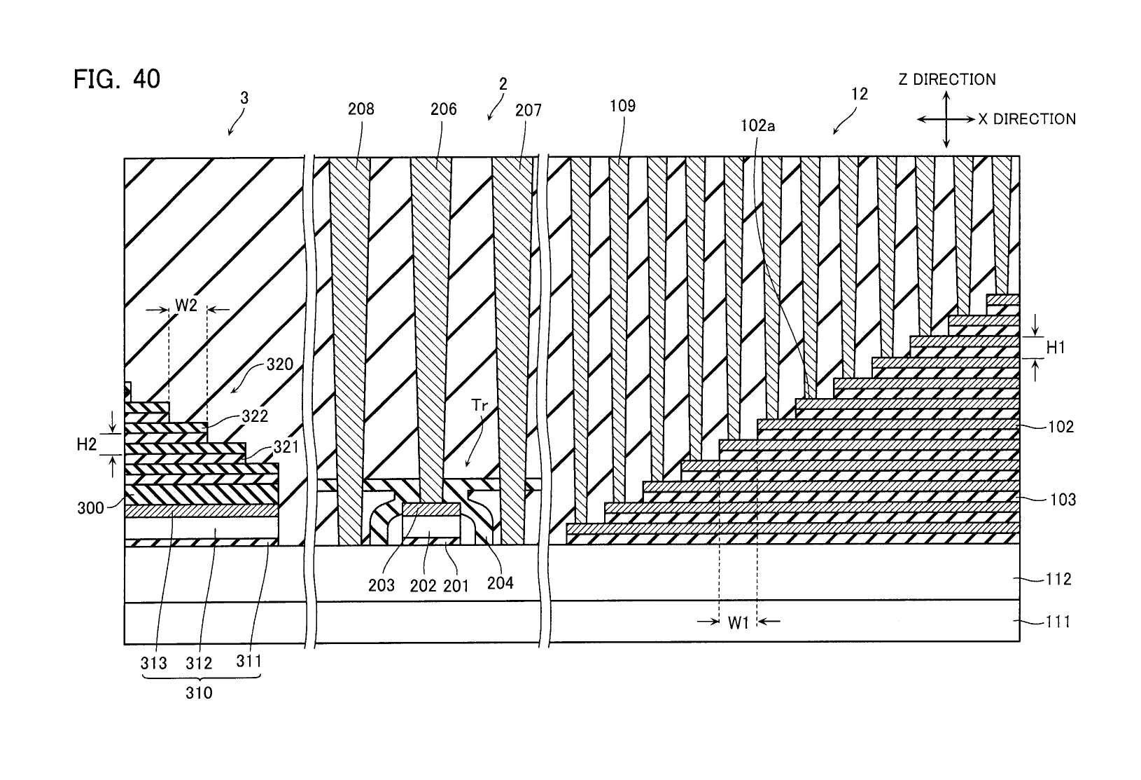

Next, with reference to FIGS. 39 and 40, the following describes the constitution of the semiconductor memory device according to yet another embodiment. FIG. 39 is the perspective view schematically illustrating the memory cell array 1 according to the modification. FIG. 40 is the cross-sectional view illustrating the memory cell array 1 according to the modification.

This semiconductor memory device according to this modification is basically similarly constituted to the semiconductor memory device according to the first embodiment. However, according to the modification, the circuit layer 112 is provided substrate 111 and the plurality of the conducting layer 102. The substrate 111 is a semiconductor substrate. The circuit layer 112 includes, for example, FETs (Field Effect Transistors), wirings, and so on.

Furthermore, in the modification, the back gate BG is provided inside the circuit layer 112 via the insulating layer (not shown). The back gate BG is connected to the lower ends of the memory unit MU and the source contact L1.

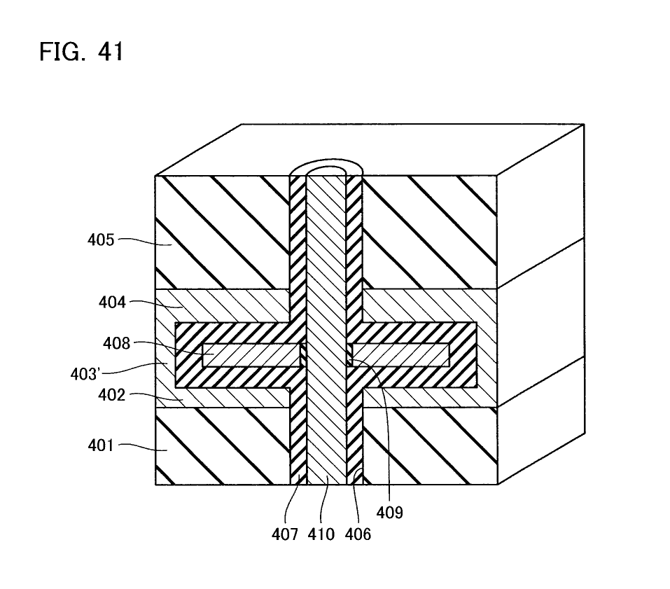

FIG. 41 shows an example of a memory cell included in the embodiments. In FIG. 41, a floating gate electrode 408 is provided on a side wall of a columnar shaped semiconductor 410 via a tunnel insulating film 409. A channel region could be formed at the columnar shaped semiconductor 410.

Control gate electrodes 402 and 404 are provided above and below the floating gate electrode 408 via a block insulating film 407. The floating gate electrode 408 could be formed so as to surround the columnar shaped semiconductor 410 in ring ring shape. The control gate electrodes 402 and 404 could be provided on the side wall of the columnar shaped semiconductor 410 via the block insulating film 407. A control gate electrode 403′ is provided on the outer circumferential side wall of the floating gate electrode 408 via the block insulating film 407. The floating gate electrode 408 is surrounded by the control electrodes 402, 403′, and 404 via the block insulating film 407. In a case in which the control electrodes 402, 403′, and 404 are made of polysilicon

An inter-layer dielectric film 401 is formed under the control gate electrode 402 and an inter-layer dielectric film 405 is formed over the control gate electrode 404. A through hole 406 is formed in the inter-layer dielectric films 401 and 405 and the control gate electrodes 402 and 404. The columnar semiconductor 410 is embedded in the through hole 406 via the block dielectric film 407 to penetrate through the floating gate electrode 408.

For example, a doped semiconductor doped with N-type impurities can be used for the control gate electrodes 402, 403′, and 4, and a polycrystalline semiconductor can be used for the floating gate electrode 408 and the columnar semiconductor 410. As these semiconductors, for example, Si, Ge, SiGe, SiC, SiSn, PbS, GaAs, InP, GaP, GaN, InGaAsP, or ZnSe can be used. Moreover, for example, a silicon oxide film can be used for the block dielectric film 407, the tunnel dielectric film 409, and the inter-layer dielectric film 401.

In the above first embodiment, the floating gate electrode 408 is surrounded by the control gate electrodes 402, 403′, and 404. Therefore, the coupling ratio between the control gate electrodes 402, 403′, and 404 and the floating gate electrode 408 can be improved while suppressing complication of the manufacturing process.

An applied voltage to the control gate electrodes 402, 403′, and 404 can be made small by improving the coupling ratio between the control gate electrodes 402, 403′, and 404 and the floating gate electrode 408, and therefore power consumption can be reduced.

Moreover, a threshold voltage can be reduced by improving the coupling ratio between the control gate electrodes 402, 403′, and 404 and the floating gate electrode 408. Therefore, a driving current of a memory cell can be increased, enabling to improve the operation speed.

Furthermore, the floating gate electrode 408 is used as a charge storage layer, so that erasing can be performed by tunneling electrons via the tunnel dielectric film 409. Therefore, erasing time can be shortened compared with the case of using a dielectric film, and therefore the erasing efficiency can be improved.

Moreover, the floating gate electrode 408 is used as a charge storage layer, so that electric field concentration can be suppressed from occurring at the floating gate electrode 408. Therefore, even in the case where the floating gate electrode 408 is surrounded by the control gate electrodes 402, 403′, and 404, the electric field applied to the floating gate electrode 408 via the control gate electrodes 402, 403′, and 404 can be made uniform, and the coupling ratio between the control gate electrodes 402, 403′, and 4 and the floating gate electrode 408 can be improved.

In the embodiment in FIG. 41, explanation is given for the method of arranging the control gate electrodes 402 and 404 on the side surface of the columnar semiconductor 410 via the block dielectric film 407, however, the control gate electrodes 402 and 404 can be arranged on the side surface of the columnar semiconductor 410 via a tunnel dielectric film.

Moreover, in the embodiment in FIG. 41, the configuration in which a memory cell is provided only for one layer is explained, however, the memory cell in FIG. 41 can be stacked for n layers in a height direction of the columnar semiconductor 410.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including memory cells arranged on a semiconductor substrate in a laminating direction and a plurality of conducting layers, the plurality of conducting layers being arranged on the semiconductor substrate in the laminating direction, the plurality of conducting layers being coupled to the memory cells;
a first stepped portion including the plurality of conducting layers, height of the first stepped portion decrementing with separation from the memory cell array; and
a second stepped portion having a structure in which a plurality of first layers and second layers are laminated in alternation on the semiconductor substrate in the laminating direction, the second stepped portion being disposed opposing the first stepped portion, and height of the second stepped portion incrementing with separation from the memory cell array, wherein
a lowest surface of the second stepped portion is formed at a position higher than the conducting layer at a lowest layer of the first stepped portion.

2. The semiconductor memory device according to claim 1, wherein
the second stepped portion further includes an insulating film disposed between a lowest layer of the first layers and the semiconductor substrate.

3. The semiconductor memory device according to claim 1, wherein
the number of the second layers included in the second stepped portion is less than the number of the conducting layers included in the first stepped portion.

4. The semiconductor memory device according to claim 1, further comprising
a transistor region that includes a transistor, the transistor including a gate electrode layer disposed on the semiconductor substrate.

5. The semiconductor memory device according to claim 4, wherein
the transistor region is formed in a region sandwiched between the first stepped portion and the second stepped portion.

6. The semiconductor memory device according to claim 1, wherein
the second stepped portion is formed at an edge portion of the semiconductor substrate.

7. The semiconductor memory device according to claim 4, wherein
the number of the second layers included in the second stepped portion is less than the number of the conducting layers included in the first stepped portion.

8. The semiconductor memory device according to claim 1, further comprising
a transistor region that includes a transistor, the transistor including a gate electrode layer disposed on the semiconductor substrate, wherein
the second stepped portion includes a laminated body between a lowest layer of the first layers and the semiconductor substrate, the laminated body having a structure identical to a structure of the gate electrode layer.

9. The semiconductor memory device according to claim 4, further comprising
a stopper film disposed on an upper layer of the gate electrode layer, wherein
a top surface of the stopper film coincides with undersurfaces of the plurality of either first layers or second layers of the second stepped portion.

10. The semiconductor memory device according to claim 1, wherein
the second layer is the conducting layer.

11. The semiconductor memory device according to claim 1, wherein
a top surface of the second stepped portion coincides with a top surface of the first stepped portion.

12. The semiconductor memory device according to claim 1, further comprising
a wiring portion disposed between the memory cell array and the semiconductor substrate.

13. The semiconductor memory device according to claim 1, wherein
the second layer is an insulating layer.

14. The semiconductor memory device according to claim 1, wherein
a width of each step of the second stepped portion in a direction with separation from the memory cell array coincides with a width of each step of the first stepped portion in a direction with separation from the memory cell array.

15. The semiconductor memory device according to claim 1, wherein
a height of each step of the second stepped portion in a direction with separation from the semiconductor substrate coincides with a height of each step of the first stepped portion in a direction with separation from the semiconductor substrate.

16. The semiconductor memory device according to claim 1, further comprising
a kerf portion formed at an edge portion of the semiconductor substrate, wherein
the second stepped portion is formed at the kerf portion.

17. The semiconductor memory device according to claim 1, wherein
a number of steps included in the second stepped portion is less than a number of steps included in the first stepped portion.

18. The semiconductor memory device according to claim 1, wherein
the conducting layer is a first conducting layer,
the second layer is a second conducting layer, and
a material of the second conducting layer is different from a material of the first conducting layer.

19. The semiconductor memory device according to claim 1, wherein
the first stepped portion has a disconnected portion in a direction intersecting with the direction separated from the memory cell array.

20. A semiconductor wafer comprising:
a plurality of chip portions segregated by a plurality of dicing lines, the plurality of dicing lines extending in a first direction and a second direction, the second direction intersecting with the first direction;
a memory cell array including memory cells arranged on each of the plurality of chip portions in a laminating direction and a plurality of conducting layers, the plurality of conducting layers being arranged on each of the plurality of chip portions in the laminating direction, the plurality of conducting layers being coupled to the memory cells;
a first stepped portion including the plurality of conducting layers, height of the first stepped portion decrementing with separation from the memory cell array; and
a second stepped portion having a structure in which a plurality of first layers and second layers are laminated in alternation on each of the plurality of chip portions in the laminating direction, the second stepped portion being disposed opposing the first stepped portion, and height of the second stepped portion incrementing with separation from the memory cell array; wherein
the second layer at a lowest surface of the second stepped portion is formed at a position higher than the conducting layer at a lowest layer of the first stepped portion.
